(19) United States
(12) Patent Application Publication
(10) Pub. No.: US 2026/0206568 A1
(43) Pub. Date: Jul. 16, 2026

(54) SEMICONDUCTOR DEVICE

(71) Applicant: SAMSUNG ELECTRONICS CO., LTD., Suwon-si (KR)

(72) Inventors: Myungjin CHUNG, Suwon-si (KR); Daiyun KIM, Suwon-si (KR); Inhyun SONG, Suwon-si (KR); Eunguk CHUNG, Suwon-si (KR); Keun Hwi CHO, Suwon-si (KR); Inseok HEO, Suwon-si (KR)

(73) Assignee: SAMSUNG ELECTRONICS CO., LTD., Suwon-si (KR)

(21) Appl. No.: 19/309,088

(22) Filed: Aug. 25, 2025

(30) Foreign Application Priority Data
Jan. 14, 2025 (KR) 10-2025-0005579

(51) Int. Cl. H01L 23/00; H01L 23/522; H01L 23/535

(52) U.S. Cl. CPC H10W 20/42; H10W 20/20; H10W 72/242

(57) ABSTRACT

A semiconductor device includes a substrate including active patterns on a first surface of the substrate, source/drain patterns, gate electrodes surrounding the active patterns, an upper wire structure on the first surface and connected to one of the source/drain patterns or the gate electrodes, a lower wire structure on a second surface of the substrate and connected to at least another of the source/drain patterns or the gate electrodes, a support substrate on one of the upper wire structure or the lower wire structure, first through-vias penetrating the support substrate and connected to one of the upper wire structure or the lower wire structure, first bumps on the support substrate and respectively connected to the first through-vias, and second bumps on the other one of the upper wire structure or the lower wire structure and connected to the other one of the upper wire structure or the lower wire structure.

### CROSS-REFERENCE TO RELATED APPLICATION

This application claims priority to and the benefit of Korean Patent Application No. 10-2025-0005579 filed with the Korean Intellectual Property Office on Jan. 14, 2025, the entire contents of which are incorporated herein by reference.

### BACKGROUND OF THE DISCLOSURE

### 1. Field

The present disclosure relates to a semiconductor device.

### 2. Description of the Related Art

Semiconductor devices have been continuously developed to improve integration density and performance, and to achieve these advancements, various packaging technologies and wiring structures have been introduced. In particular, the wiring structures of semiconductor devices are designed to maximize the efficiency of high-density wiring and signal transmission. These wiring structures play a crucial role in distributing input/output signals, power, and ground signals within the semiconductor chip.

Meanwhile, as the manufacturing process of highly integrated semiconductor devices becomes more complex, and designs become more miniaturized and multi-layered, defect analysis has become increasingly difficult. Defect analysis is essential for identifying the causes of defects and improving design and manufacturing processes. However, multi-layer wiring structures and miniaturized device designs make it challenging to accurately locate defects and obtain analysis data.

To address these challenges, the design of wiring and bump structures has become increasingly important. In particular, bumps provide electrical connections between the semiconductor chip and the package substrate, affecting not only signal transmission but also the efficiency of defect analysis. Conventional bump arrangements have primarily focused on signal and power transmission efficiency, but such designs often make it difficult to pinpoint defect locations during defect analysis. Therefore, a bump arrangement technology that facilitates defect analysis is required.

### SUMMARY

The present disclosure attempts to provide a semiconductor device having a bump arrangement for facilitating defect analysis.

According to an embodiment, a semiconductor device includes a substrate including a first surface and a second surface opposing each other, active patterns spaced apart from each other along a first direction on the first surface of the substrate, source/drain patterns respectively connected to both sides of the active patterns, gate electrodes surrounding the active patterns and extending in a second direction intersecting the first direction, an upper wire structure positioned on the first surface of the substrate and connected to a first one of the source/drain patterns or the gate electrodes, a lower wire structure positioned on the second surface of the substrate and connected to a second one of the source/drain patterns or the gate electrodes, a support substrate positioned on one of the upper wire structure or the lower wire structure, first through-vias penetrating the support substrate and connected to one of the upper wire structure or the lower wire structure, a plurality of first bumps positioned on the support substrate and respectively connected to the first through-vias, and a plurality of second bumps positioned on the other one of the upper wire structure or the lower wire structure and connected to the other one of the upper wire structure or the lower wire structure.

According to an embodiment, a semiconductor device includes a substrate including a first region and a second region surrounding the first region, the substrate having a first surface and a second surface opposing each other, active patterns spaced apart from each other along a first direction on the first surface of the substrate, source/drain patterns respectively connected to both sides of the active patterns, gate electrodes surrounding the active patterns and extending in a second direction intersecting the first direction, an upper wire structure positioned on the first surface of the substrate and connected to a first one of the source/drain patterns or the gate electrodes, a lower wire structure positioned on the second surface of the substrate and connected to a second one of the source/drain patterns or the gate electrodes, and a plurality of bumps connected to at least one of the upper wire structure or the lower wire structure, wherein the plurality of bumps are positioned in the second region, not in the first region.

According to an embodiment, a semiconductor device includes a plurality of first upper bumps and a first upper wire structure connected to signal lines, a plurality of first lower bumps and a first lower wire structure positioned below the first upper wire structure and connected to power lines, a first device positioned between the first upper wire structure and the first lower wire structure. The first device includes a plurality of first gate structures and first source/drain patterns positioned between the plurality of first gate structures, and the plurality of first upper bumps and the plurality of first lower bumps are positioned along an edge of a device region where the first device is positioned.

According to the embodiments, it is possible to facilitate defect analysis of a semiconductor device having a multilayer wiring structure.

### BRIEF DESCRIPTION OF THE DRAWINGS

FIGS. 1 and 2 are plan views of a semiconductor wafer having a semiconductor device formed thereon according to an embodiment.

FIGS. 3 and 4 are plan views of a semiconductor wafer having a semiconductor device formed thereon according to an embodiment.

FIG. 5 is a plan view showing a semiconductor device according to an embodiment.

FIG. 6 is a cross-sectional view taken along line A-A′ of FIG. 5 according to an embodiment.

FIG. 7 is a cross-sectional view taken along line A-A′ of FIG. 5 according to an embodiment.

FIG. 8 is a cross-sectional view taken along line A-A′ of FIG. 5 according to an embodiment.

FIG. 9 is a cross-sectional view taken along line A-A′ of FIG. 5 according to an embodiment.

FIG. 10 is a cross-sectional view taken along line A-A′ of FIG. 5 according to an embodiment.

FIGS. 11 to 17 are cross-sectional views showing a method of manufacturing a semiconductor device according to an embodiment of the present disclosure in the order of processes.

FIGS. 18 to 20 are intermediate step drawings illustrating a method of manufacturing a semiconductor device according to some embodiments.

FIGS. 21 to 26 are intermediate step drawings for explaining a method of manufacturing a semiconductor device according to some embodiments.

### DETAILED DESCRIPTION OF THE EMBODIMENTS

Hereinafter, various embodiments of the present disclosure will be described in detail with reference to the attached drawings so that a person having ordinary skill in the art to which the present disclosure pertains may easily implement the disclosure. The present disclosure may be embodied in many different forms and is not limited to the embodiments described herein.

In order to clearly explain the present disclosure, parts irrelevant to the description are omitted, and the same reference numerals are used for identical or similar components throughout the specification.

In addition, the size and thickness of each component shown in the drawing are arbitrarily shown for convenience of explanation, so the present disclosure is not necessarily limited to what is shown. In the drawings, the thickness of layers, films, panels, regions, etc., are exaggerated for clarity. And in the drawings, for convenience of explanation, the thickness of some layers and regions is exaggerated.

Also, it will be understood that when an element such as a layer, film, region, or substrate is referred to as being “on” another element, it may be directly on the other element or intervening elements may also be present. In contrast, when an element is referred to as being “directly on” another element, there are no intervening elements present. Also, being “above” or “on” a reference part means being positioned above or below the reference part, and does not necessarily mean being positioned “above” or “on” the opposite direction of gravity.

In addition, unless explicitly described to the contrary, the word “comprise”, and variations such as “comprises” or “comprising”, will be understood to imply the inclusion of stated elements but not the exclusion of any other elements.

Additionally, throughout the specification, when we say “in plan”, we mean when the target portion is viewed from above, and when we say “in cross section”, we mean when the target portion is viewed from the side in a cross-section cut vertically.

Additionally, throughout the specification, two directions parallel to the upper surface of the substrate are defined as a first direction D1 and a second direction D2, respectively, and the direction perpendicular to the upper surface of the substrate is described as a third direction D3. For example, the first direction D1 and the second direction D2 may be orthogonal to each other.

In the drawings relating to a semiconductor device according to an embodiment, by way of example, a GAA (Gate All Around) and MBCFET™(Multi-Bridge Channel Field Effect Transistor) including nanowires or nanosheets are illustrated, but the disclosure is not limited thereto. According to an embodiment, the semiconductor device may include a fin-type transistor (FinFET) including a channel region in a fin-type pattern shape, a tunneling transistor (tunneling FET), a 3D-SFET (3D Stack Field Effect Transistor) structure, and a CFET (Complementary Field Effect Transistor) structure.

Hereinafter, a semiconductor device according to an embodiment of the present disclosure may be used in various memory devices and systems including wiring structures. For example, semiconductor devices may be applied to wiring structures included in logic devices such as central processing units (CPUs, MPUs), application processors (APs), etc. Alternatively, the semiconductor device may be applied to a wiring structure used in a memory peripheral circuit region or cell region of a volatile memory device such as a DRAM device or an SRAM device, or a nonvolatile memory device such as a flash memory device, a PRAM device, an MRAM device, or an RRAM device.

Hereinafter, a semiconductor device according to an embodiment will be described with reference to the drawings.

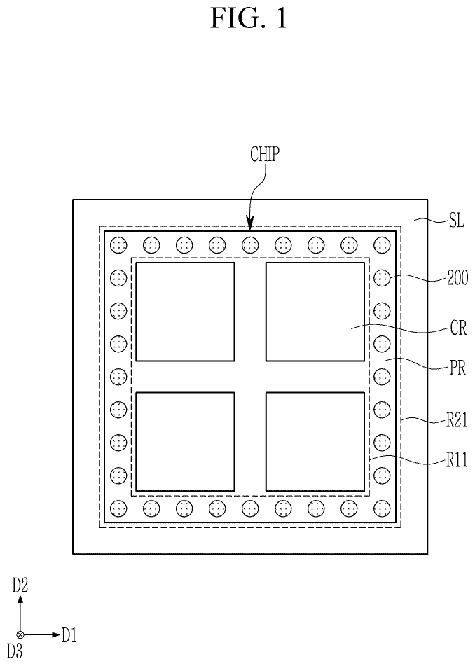

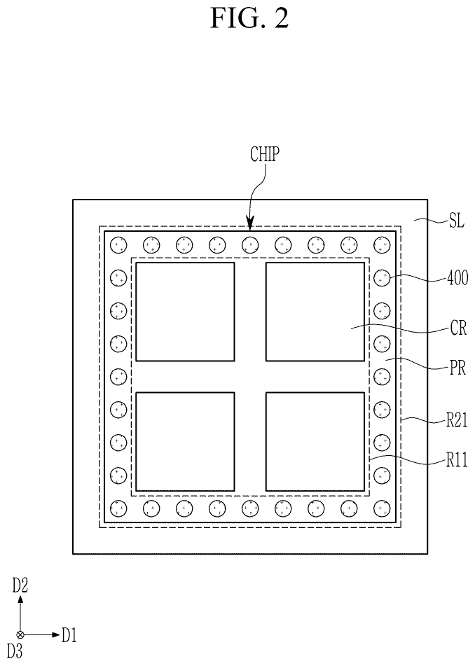

FIGS. 1 and 2 are plan views of a semiconductor wafer having a semiconductor device formed thereon according to an embodiment. FIG. 1 is a plan view showing the front surface of a semiconductor wafer according to an embodiment. FIG. 2 is a plan view showing the back surface of a semiconductor wafer according to an embodiment.

Referring to FIGS. 1 and 2, a semiconductor wafer may include semiconductor chip regions CHIP and scribe lane regions SL between the semiconductor chip regions CHIP. Additionally, the semiconductor chip region CHIP may include a cell region CR and a peripheral region PR. In other words, one or more cell regions CR and peripheral regions PR may form one semiconductor chip region CHIP, and the scribe lane regions SL may be arranged to surround the semiconductor chip regions CHIP. Logic transistors that constitute the logic circuit of a semiconductor device may be placed in the cell region CR. Transistors that constitute the processor core or I/O terminals of the cell region CR may be placed in the peripheral region PR.

Although FIGS. 1 and 2 illustrate that a plurality of cell regions CR are arranged in a matrix form and that a peripheral region PR surrounds the cell regions CR, the present disclosure is not limited to this arrangement, and the cell regions CR and the peripheral regions PR may have any appropriate arrangement. Additionally, the number of cell regions CR forming one semiconductor chip region CHIP is not limited to that shown.

The scribe lane region SL corresponds to a region for performing dicing, which separates a semiconductor wafer into individual semiconductor chips, after forming semiconductor devices in the semiconductor chip region CHIP. Although not shown, the scribe lane region SL may include a key region. The key region may include align keys or overlay keys used in exposure processes performed to form semiconductor devices on a semiconductor chip region CHIP.

Referring to FIGS. 1 and 2, a semiconductor chip region CHIP according to an embodiment may include an eleventh region R11 and a twenty-first region R21 surrounding the eleventh region R11. In other words, the twenty-first region R21 may be positioned outside the eleventh region R11.

According to an embodiment, the twenty-first region R21 may correspond to an edge region of a semiconductor chip region CHIP. The eleventh region R11 may correspond to a region of the semiconductor chip region CHIP excluding the twenty-first region R21. In other words, the eleventh region R11 may correspond to a region surrounded by the twenty-first region R21.

According to an embodiment, the eleventh region R11 may not have a plurality of first bumps 200 and/or a plurality of second bumps 400 positioned thereon. According to an embodiment, a plurality of first bumps 200 and/or a plurality of second bumps 400 may be positioned in the twenty-first region R21. In the present disclosure, the first bump 200 may refer to a bump positioned on the front surface of a semiconductor device, and the second bump 400 may refer to a bump positioned on the back surface of the semiconductor device.

Referring to FIG. 1, from a planar perspective looking at the front surface of the semiconductor device, the twenty-first region R21 in which a plurality of first bumps 200 are arranged may have a closed shape or loop shape extending along the edge of the semiconductor chip region CHIP. In other words, from a planar perspective looking at the front surface of the semiconductor device, the plurality of first bumps 200 may not be positioned in the central region of the semiconductor chip region CHIP.

Referring to FIG. 2, from a planar perspective looking at the back of the semiconductor device, the twenty-first region R21 in which a plurality of second bumps 400 are arranged may have a closed shape or loop shape extending along the edge of the semiconductor chip region CHIP. In other words, from a planar perspective looking at the back of the semiconductor device, the plurality of second bumps 400 may not be positioned in the central region of the semiconductor chip region CHIP.

As described above, since the plurality of first bumps 200 and/or the plurality of second bumps 400 of the semiconductor device according to the present disclosure have a structure in which they are arranged only at the edge of the semiconductor chip region CHIP, it may be easy to analyze a defect in the semiconductor device using a laser-based optical method. In other words, since the optical signal of the laser is not interfered with by reflection and scattering caused by the bumps being arranged in the central region within the semiconductor chip region CHIP, the quality of the analysis signal is improved and the accuracy of the analysis of the cause of the defect may be increased.

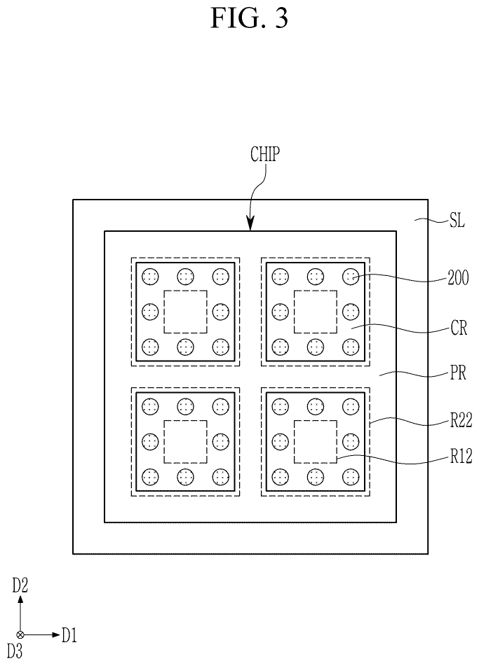

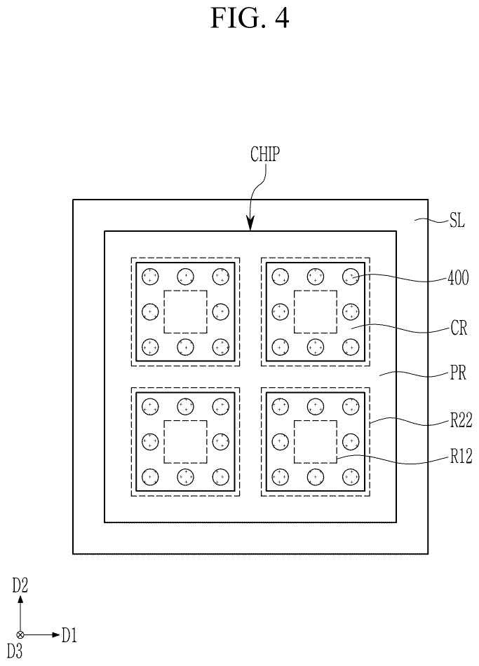

FIGS. 3 and 4 are plan views of a semiconductor wafer having a semiconductor device formed thereon according to an embodiment. FIG. 3 is a plan view showing the front surface of a semiconductor wafer according to an embodiment. FIG. 4 is a plan view showing the back surface of a semiconductor wafer according to an embodiment. The semiconductor wafers illustrated in FIGS. 3 and 4 may include components similar to or identical to the semiconductor wafers described with reference to FIGS. 1 and 2. Specifically, the semiconductor wafer illustrated in FIGS. 3 and 4 may include a semiconductor chip region CHIP and a scribe lane region SL between the semiconductor chip regions CHIP. Additionally, the semiconductor chip region CHIP may include a cell region CR and a peripheral region PR. Here, any overlapping content with that described above in FIGS. 1 and 2 will be briefly explained or omitted, and the differences will be mainly explained.

Referring to FIGS. 3 and 4, a semiconductor chip region CHIP according to an embodiment may include a plurality of cell regions CR. Each of the plurality of cell regions CR may include a twelfth region R12 and a twenty-second region R22 surrounding the twelfth region R12. In other words, the twenty-second region R22 may be positioned outside the twelfth region R12.

According to an embodiment, the twenty-second region R22 may correspond to an edge region of the cell region CR. The twelfth region R12 may correspond to a region of the cell region CR excluding the twenty-second region R22. In other words, the twelfth region R12 may correspond to a region surrounded by the twenty-second region R22.

According to an embodiment, the twelfth region R12 may not have a plurality of first bumps 200 and/or a plurality of second bumps 400 positioned therein. According to an embodiment, a plurality of first bumps 200 and/or a plurality of second bumps 400 may be positioned in the twenty-second region R22. Here, the first bump 200 may refer to a bump positioned on the front surface of the semiconductor device, and the second bump 400 may refer to a bump positioned on the back surface of the semiconductor device.

Referring to FIG. 3, from a planar perspective looking at the front surface of the semiconductor device, the twenty-second region R22 in which a plurality of first bumps 200 are arranged may have a closed shape or loop shape extending along the edge of the cell region CR. In other words, from a planar perspective looking at the front surface of the semiconductor device, the plurality of first bumps 200 may not be positioned in the central region of the cell region CR.

Referring to FIG. 4, from a planar perspective looking at the back of the semiconductor device, the twenty-second region R22 in which a plurality of second bumps 400 are arranged may have a closed shape or loop shape extending along the edge of the cell region CR. In other words, from a planar perspective looking at the back of the semiconductor device, the plurality of second bumps 400 may not be positioned in the central region of the cell region CR.

As described above, since the semiconductor device according to the present disclosure has a structure in which the plurality of first bumps 200 and/or the plurality of second bumps 400 are arranged only at the edge of the cell region CR, it may be easy to analyze a defect in the semiconductor device using a laser-based optical method. In other words, since the optical signal of the laser is not interfered with by reflection and scattering caused by the bumps being arranged in the central region within the cell region CR, the quality of the analysis signal is improved, and the accuracy of the analysis of the cause of the defect may be increased.

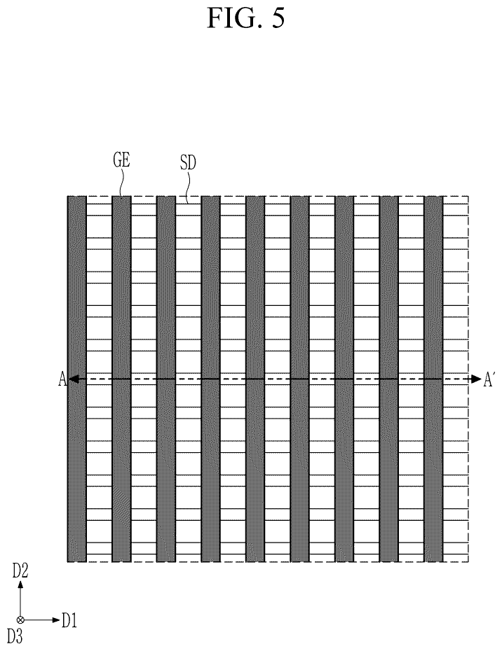

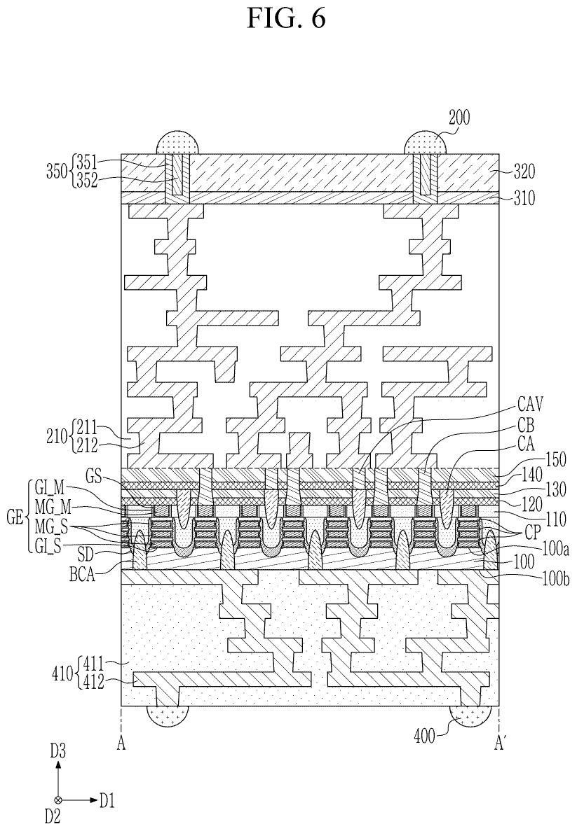

FIG. 5 is a plan view showing a semiconductor device according to an embodiment. FIG. 6 is a cross-sectional view taken along line A-A′ of FIG. 5 according to an embodiment.

For clarity and simplicity of illustration, FIG. 5 mainly depicts the gate structure GE and the source/drain pattern SD. Referring to FIG. 5, the gate structures GE may be spaced apart in a first direction D1 and extended along a second direction D2. The source/drain pattern SD is positioned between the gate structures GE in the first direction D1 and may be spaced apart in the second direction D2.

Referring to FIGS. 5 and 6, a semiconductor device according to an embodiment may include a channel pattern CP spaced apart along a first direction D1 on a first surface 100a of a substrate 100, source/drain patterns SD connected to both sides of the channel pattern CP, and a gate structure GE surrounding the channel pattern CP and extending in a second direction D2.

According to an embodiment, a logic cell may be provided on a substrate 100. Logic transistors that constitute a logic circuit may be placed on a logic cell. According to an embodiment, the upper surface of the substrate 100 may be formed as a plane parallel to a first direction D1 and a second direction D2 intersecting the first direction D1.

According to an embodiment, the substrate 100 may be an insulating substrate including an insulating material. The substrate 100 may include an oxide, a nitride, a nitride, or a combination thereof. For example, the substrate 100 may include silicon nitride (SiNx). The substrate 100 is depicted as a single layer, but this is only for convenience of explanation and is not limited thereto.

According to an embodiment, the first surface 100a and the second surface 100b of the substrate 100 may be formed as planes parallel to the first direction D1 and the second direction D2 intersecting the first direction D1. For example, the first surface 100a of the substrate 100 may be the upper surface, and the second surface 100b may be the lower surface. The upper surface of the substrate 100 is a surface opposite the lower surface of the substrate 100 in the third direction D3. The third direction D3 may be a direction perpendicular to the first direction D1 and the second direction D2. The lower surface of the substrate 100 may be referred to as the back side of the substrate 100. In some embodiments, the logic circuitry of the cell region may be implemented on the upper surface of the substrate 100. In some embodiments, the upper wire structure 210 and the plurality of first bumps 200 described below may be positioned on the first surface 100a of the substrate 100. In some embodiments, the lower wire structure 410 and the plurality of second bumps 400 described below may be positioned on the second surface 100b of the substrate 100.

According to an embodiment, the channel patterns CP may be arranged spaced apart in a first direction D1 on the substrate 100. According to an embodiment, a plurality of channel patterns CP may be arranged spaced apart from each other in a third direction D3.

For example, each of the plurality of channel patterns CP may have a sheet shape. Each of the plurality of channel patterns CP may be a nanosheet having a thickness of several nanometers along the third direction D3.

According to an embodiment, the channel pattern CP may provide a path for current to flow between the source/drain patterns SD described below. For example, a channel pattern CP may be placed between source/drain patterns SD to connect the source/drain patterns SD.

According to an embodiment, the channel pattern CP may penetrate a portion of the gate structure GE in a direction (e.g., a first direction D1) that intersects the direction in which the gate structure GE extends, which will be described later. In FIG. 6, three channel patterns CP are depicted as being arranged spaced apart in the third direction D3, but this is not limited thereto, and the number of stacked channel patterns CP may be changed in various ways.

According to an embodiment, the channel patterns CP may include a semiconductor material. For example, channel patterns CP may include group IV semiconductors such as Si, Ge, group III-V compound semiconductors, group II-VI compound semiconductors, etc.

According to an embodiment, the gate structure GE may extend in a second direction D2 on the substrate 100. The gate structures GE may be arranged spaced apart from each other in the first direction D1.

According to an embodiment, the gate structure GE may include a plurality of sub-gate structures MG_S and GI_S and a main gate structure MG_M and GI_M. The sub-gate structure MG_S and GI_S may be positioned on the substrate 100, and the main gate structure MG_M and GI_M may be positioned on the sub-gate structure MG_S and GI_S.

Each of the sub-gate structures MG_S and GI_S may be composed of multiple layers. For example, each of the sub-gate structures MG_S and GI_S may include a sub-gate electrode MG_S and a sub-gate insulating layer GI_S.

According to an embodiment, the sub-gate structures MG_S and GI_S and the channel patterns CP may be alternately stacked in a third direction D3. According to an embodiment, the sub-gate electrode MG_S may surround the channel patterns CP.

In FIG. 6, three sub-gate structures MG_S and GI_S are depicted as being arranged spaced apart in the third direction D3, but the number of sub-gate structures MG_S and GI_S arranged spaced apart is not limited thereto. For example, a gate structure GE may include four sub-gate structures MG_S and GI_S.

The sub-gate electrode MG_S may include at least one of a metal, a metal alloy, a conductive metal nitride, a metal silicide, a doped semiconductor material, a conductive metal oxide, and a conductive metal nitride. The sub-gate electrode MG_S is, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbide nitride (TiAlC-N), titanium aluminum carbide (TiAlC), titanium carbide (TiC), tantalum carbide nitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), It may include at least one of, but is not limited to, molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. The conductive metal oxides and conductive metal nitrides may include, but are not limited to, oxidized forms of the materials described above.

Although not explicitly shown, the sub-gate insulating layer GI_S may extend along the first surface 100a of the substrate 100. A sub-gate insulating layer GI_S may be positioned along the periphery of a plurality of sub-gate electrodes MG_S. The sub-gate insulating layer GI_S may be in contact with the first surface 100a of the substrate 100 and a plurality of channel patterns CP. A sub-gate insulating layer GI_S may be interposed between a plurality of channel patterns CP and a plurality of sub-gate electrodes MG_S. According to an embodiment, the sub-gate insulating layer GI_S may include various insulating materials.

Although not shown in FIG. 6, the semiconductor device according to the embodiment may further include an internal gate spacer positioned between the sub-gate insulating layer GI_S and the source/drain patterns SD described below.

According to an embodiment, the sub-gate insulating layer GI_S is illustrated as a single layer, but is not limited thereto. For example, the sub-gate insulating layer GI_S may include silicon oxide, silicon oxynitride, or silicon nitride. Alternatively, for example, the sub-gate insulating layer GI_S may include a high-k material. Alternatively, for example, the sub-gate insulating layer GI_S may include both silicon oxide and a high-k material. The high-k material may include materials with a dielectric constant higher than silicon oxide (SiO₂), such as hafnium oxide (HfO), aluminum oxide (AlO), or tantalum oxide (TaO).

According to an embodiment, the main gate structure MG_M and GI_M may be positioned on top of the sub-gate structure MG_S and GI_S and the plurality of channel patterns CP. The main gate structure MG_M and GI_M may be positioned on the upper surface of the channel pattern CP positioned at the uppermost position among the plurality of channel patterns CP.

According to an embodiment, the main gate structure MG_M and GI_M may include a main gate electrode MG_M and a main gate insulating layer GI_M. According to an embodiment, the main gate electrode MG_M may be positioned on the sub-gate structures MG_S and GI_S and the plurality of channel patterns CP. Also, although not shown, four sides of the multiple channel patterns CP may be surrounded by gate electrodes MG_M and MG_S.

According to an embodiment, the main gate electrode MG_M may include the same material as the sub-gate electrode MG_S. For example, the main gate electrode MG_M may include at least one of a metal, a metal alloy, a conductive metal nitride, a metal silicide, a doped semiconductor material, a conductive metal oxide, and a conductive metal nitride.

According to an embodiment, the main gate insulating layer GI_M may extend along the side and bottom surfaces of the main gate electrode MG_M. The main gate insulating layer GI_M may extend along the side of the gate spacer GS, which will be described later. According to an embodiment, the main gate insulating layer GI_M may include various insulating materials.

According to an embodiment, the main gate insulating layer GI_M is illustrated as a single layer, but is not limited thereto. For example, the main gate insulating layer GI_M may be formed of a multilayer including silicon oxide (SiO₂) and a high-k material. At this time, the high-k material may include a material having a higher dielectric constant than silicon oxide (SiO₂), such as hafnium oxide (HfO), aluminum oxide (AlO), or tantalum oxide (TaO).

A semiconductor device according to an embodiment may further include a gate spacer GS positioned on both sides of a main gate electrode MG_M. The gate spacer GS may not be placed between the substrate 100 and the channel pattern CP. According to an embodiment, the gate spacer GS may not be placed between a plurality of channel patterns CP adjacent in the third direction D3.

The gate spacer GS may include, for example, at least one of silicon nitride (SiN), silicon oxynitride (SiON), silicon oxide (SiO₂), silicon carbonitride (SiOCN), silicon boron nitride (SiBN), silicon oxyboron nitride (SiOBN), silicon oxycarbide (SiOC), and combinations thereof. The gate spacer GS is depicted as a single layer, but this is for convenience of explanation only and is not limited thereto.

According to an embodiment, the source/drain patterns SD may be arranged spaced apart along a first direction D1 on the substrate 100. A channel pattern CP and a gate structure GE may be positioned between the source/drain patterns SD. In other words, a plurality of source/drain patterns SD and a plurality of channel patterns CP may be alternately arranged along a first direction D1 on a substrate 100. As illustrated in FIG. 5, the source/drain patterns SD may also be arranged in the second direction D2. Specifically, the source/drain patterns SD may be arranged spaced apart from each other along the second direction D2 on the substrate 100.

According to an embodiment, the source/drain pattern SD may be positioned on both sides of the channel patterns CP and/or the sub-gate structures MG_S and GI_S. Specifically, two source/drain patterns SD may be arranged spaced apart in a direction (e.g., a first direction D1) intersecting a direction in which the gate structure GE extends, with channel patterns CP and/or sub-gate structures MG_S and GI_S therebetween. The upper surface of the source/drain pattern SD may be positioned at substantially the same level as the upper surface of the channel pattern CP positioned at the uppermost position among the channel patterns CP, but is not limited thereto. The source/drain pattern SD may be in contact with the channel pattern CP and the sub-gate structures MG_S and GI_S.

According to an embodiment, the side surface of the source/drain pattern SD may have an uneven embossed shape. In other words, the side of the source/drain pattern SD may have a wavy profile. For example, a side surface of a source/drain pattern SD adjacent to a sub-gate structure MG_S and GI_S may have a roughly convex shape toward the sub-gate structure MG_S and GI_S, and a side surface of a source/drain pattern SD adjacent to the channel patterns CP may have a roughly concave shape toward the channel patterns CP. However, it is not limited thereto, and the side shape of the source/drain pattern SD may be changed in various ways. For example, the side shape of the source/drain pattern SD may have a flat shape.

According to an embodiment, the source/drain patterns SD may be epitaxial patterns formed by a selective epitaxial growth process using the channel pattern CP as a seed. According to an embodiment, the source/drain patterns SD may include Si or SiGe. However, the material of the source/drain pattern SD is not limited to this and may be changed in various ways. A source/drain pattern SD may serve as the source/drain of a transistor that uses channel patterns CP as a channel region.

According to an embodiment, the source/drain pattern SD may be multilayer. However, this is not limited to the source/drain pattern SD and the source/drain pattern SD may be formed as a single layer.

According to an embodiment, the lower surface of the source/drain pattern SD may be positioned at a lower level than the lower surface of the sub-gate structure MG_S and GI_S. For example, as illustrated in FIG. 6, the lower surface of the source/drain pattern SD may be positioned closer to the bottom surface of the substrate 100 than the lower surface of the sub-gate structure MG_S and GI_S positioned at the bottom.

According to an embodiment, the semiconductor device may further include first to fifth interlayer insulating layers 110, 120, 130, 140 and 150. According to an embodiment, the semiconductor device may further include a contact pattern CA and a contact via CAV connected to at least one source/drain pattern SD. According to an embodiment, the semiconductor device may further include a gate contact pattern CB connected to at least one gate structure GE.

According to an embodiment, the first interlayer insulating layer 110 may cover the source/drain pattern SD. Additionally, the first interlayer insulating layer 110 may be positioned between the main gate electrode MG_M and the contact pattern CA. For example, the first interlayer insulating layer 110 may be positioned between the gate spacer GS and the contact pattern CA.

For example, the first interlayer insulating layer 110 may include silicon oxide. Although the first interlayer insulating layer 110 is illustrated as a single layer, it is not limited thereto, and the first interlayer insulating layer 110 may be formed of a multi-layer in which multiple layers are laminated.

According to an embodiment, the second interlayer insulating layer 120 may be positioned on the first interlayer insulating layer 110. For example, the second interlayer insulating layer 120 is positioned on the main gate electrode MG_M and may cover the main gate electrode MG_M. In other words, the second interlayer insulating layer 120 may replace the gate capping pattern and the upper insulating pattern.

For example, the second interlayer insulating layer 120 may include silicon nitride. Although the second interlayer insulating layer 120 is illustrated as a single layer, it is not limited thereto, and the second interlayer insulating layer 120 may be formed of a multi-layer in which multiple layers are laminated.

According to an embodiment, the third interlayer insulating layer 130 may be positioned on the second interlayer insulating layer 120. Additionally, the third interlayer insulating layer 130 may be positioned between the contact pattern CA and the gate contact pattern CB. For example, the third interlayer insulating layer 130 may include silicon oxide. Although the third interlayer insulating layer 130 is illustrated as a single layer, it is not limited thereto, and the third interlayer insulating layer 130 may be formed of a multi-layer in which multiple layers are laminated.

According to an embodiment, the fourth interlayer insulating layer 140 may be positioned on the third interlayer insulating layer 130. For example, the fourth interlayer insulating layer 140 is positioned on the contact pattern CA and may cover the contact pattern CA.

According to an embodiment, the fourth interlayer insulating layer 140 may have an upper portion and a lower portion facing in the third direction D3. The lower part of the fourth interlayer insulating layer 140 is positioned closer to the substrate 100 than the upper part. With respect to the substrate 100, the lower level of the fourth interlayer insulating layer 140 may be substantially the same as the upper level of the contact pattern CA. In other words, the lower portion of the fourth interlayer insulating layer 140 and the upper portion of the contact pattern CA may be positioned at substantially the same level from the substrate 100 in the third direction D3.

For example, the fourth interlayer insulating layer 140 may include silicon nitride. Although the fourth interlayer insulating layer 140 is illustrated as a single layer, it is not limited thereto, and the fourth interlayer insulating layer 140 may be formed of a multi-layer in which multiple layers are laminated.

According to an embodiment, the fifth interlayer insulating layer 150 may be positioned on the fourth interlayer insulating layer 140. According to an embodiment, the fifth interlayer insulating layer 150 may have a predetermined thickness along the third direction D3 from the upper portion of the fourth interlayer insulating layer 140 to the lower portion of the upper wire structure 210 described below.

According to an embodiment, the fifth interlayer insulating layer 150 may have through holes opening in the third direction D3. In other words, the through holes may extend in the third direction D3 from the bottom to the top of the fifth interlayer insulating layer 150.

According to an embodiment, a contact via CAV and a gate contact pattern CB may be inserted into the through holes of the fifth interlayer insulating layer 150. In other words, the through holes of the fifth interlayer insulating layer 150 may be arranged at positions that overlap with the contact via CAV and the gate contact pattern CB in the third direction D3.

According to an embodiment, the width of the through holes into which the contact vias CAV are inserted in the first direction D1 may be substantially equal to the maximum width of the contact pattern CA in the first direction D1. However, it is not limited thereto, and the width of the through holes into which the contact via CAV is inserted in the first direction D1 may be smaller than the maximum width of the contact pattern CA in the first direction D1. Additionally, the width of the through holes into which the gate contact pattern CB is inserted in the first direction D1 may be substantially the same as the maximum width of the main gate electrode MG_M in the first direction D1. However, it is not limited thereto, and the width of the through holes into which the gate contact pattern CB is inserted in the first direction D1 may be smaller than the maximum width of the main gate electrode MG_M in the first direction D1.

According to an embodiment, the contact pattern CA may be positioned over at least one of the source/drain patterns SD. According to an embodiment, the contact pattern CA may penetrate the first interlayer insulating layer 110, the second interlayer insulating layer 120, and the third interlayer insulating layer 130 and be connected to at least one of the source/drain patterns SD.

According to an embodiment, the contact pattern CA may be positioned adjacent to the main gate electrode MG_M in the first direction D1. According to an embodiment, the contact pattern CA may electrically connect at least some of the upper wires 212 positioned in the upper wire structure 210 described below and at least one of the source/drain patterns SD.

For example, the contact pattern CA may include at least one of a metal, a metal alloy, a conductive metal nitride, a conductive metal carbide, a conductive metal oxide, a conductive metal carbonitride, and a two-dimensional (2D) material. The metal may include at least one of titanium (Ti), tantalum (Ta), tungsten (W), nickel (Ni), cobalt (Co), and platinum (Pt). The conductive metal nitride may include at least one of titanium nitride (TiN), tantalum nitride (TaN), tungsten nitride (WN), nickel nitride (NiN), cobalt nitride (CoN), and platinum nitride (PtN).

According to an embodiment, the gate contact pattern CB may be positioned on at least one of the main gate structures MG_M and GI_M. According to an embodiment, the gate contact pattern CB may penetrate the second interlayer insulating layer 120, the third interlayer insulating layer 130, the fourth interlayer insulating layer 140, and the fifth interlayer insulating layer 150 and be connected to at least one of the main gate electrodes MG_M.

According to an embodiment, the gate contact pattern CB may electrically connect at least some of the upper wires 212 positioned in the upper wire structure 210 described below and at least one of the main gate electrodes MG_M. For example, the gate contact pattern CB may include aluminum, copper, tungsten, molybdenum, cobalt, or a combination thereof.

According to an embodiment, the semiconductor device may further include an upper wire structure 210 positioned on the fifth interlayer insulating layer 150.

According to an embodiment, the upper wire structure 210 may include an upper insulating layer 211, upper wires 212, and upper vias. The upper wires 212 and upper vias may include a metal (e.g., copper).

According to an embodiment, an upper insulating layer 211 may be placed between the upper wires 212 and the upper vias to insulate them. The upper insulating layer 211 may cover the fifth interlayer insulating layer 150. The upper wires 212 and upper vias may be positioned within the upper insulating layer 211.

For example, the upper insulating layer 211 may include at least one of silicon oxide (SiOx), silicon nitride (SiNx), silicon oxynitride (SiON), or low-k dielectric layers.

According to an embodiment, at least some of the upper wires 212 may be electrically connected to at least one of the main gate electrode MG_M and the source/drain patterns SD.

According to an embodiment, an electrical signal or power voltage supplied from the outside may be provided to the source/drain pattern SD through the upper wires 212 and the contact pattern CA to the upper wires 212. According to an embodiment, an electrical signal or power voltage supplied from the outside may be provided to the main gate electrode MG_M through the upper wires 212 and the gate contact pattern CB connected to the upper wires 212.

According to an embodiment, the semiconductor device may further include a first adhesive layer 310 positioned on an upper wire structure 210, a first support substrate 320 positioned on the first adhesive layer 310, a first through-via 350 penetrating the first support substrate 320, and a plurality of first bumps 200 connected to the first through-via 350 on the first support substrate 320.

According to an embodiment, the first adhesive layer 310 may be positioned between the upper wire structure 210 and the first support substrate 320. According to an embodiment, the first support substrate 320 may be bonded to the upper wire structure 210 by the first adhesive layer 310. For example, the first adhesive layer 310 may include SiCN, AlN, tetraethylorthosilicate (TEOS), or a combination thereof.

According to an embodiment, a first support substrate 320 including one side and the other side facing each other may be positioned on a first adhesive layer 310. A first adhesive layer 310 may be positioned on one surface of a first support substrate 320, and a plurality of first bumps 200, described later, may be positioned on the other surface of the first support substrate 320. According to an embodiment, the first support substrate 320 may have through holes opening in a third direction D3. In other words, the through holes may extend in the third direction D3 from the bottom to the top of the first support substrate 320. According to an embodiment, a first through-via 350 described below may be inserted into the through-holes.

For example, the first support substrate 320 may include a silicon, germanium, silicon-germanium, gallium-arsenide (GaAs), glass, plastic, ceramic substrate, or the like. For example, the first support substrate 320 may be formed of a silicon substrate or a glass substrate.

According to an embodiment, the first through-via 350 may penetrate the first support substrate 320 and the first adhesive layer 310. Specifically, the first through-via 350 may pass through the first support substrate 320 and the first adhesive layer 310 to be connected to at least some of the upper wires 212.

According to an embodiment, the first through-via 350 may include a first metal pattern 352 penetrating the first support substrate 320 and a first metal nitride layer 351 surrounding the sidewalls and bottom surface of the first metal pattern 352.

According to an embodiment, the first metal nitride layer 351 may be conformally positioned on the inner surface of the through holes of the first support substrate 320. In other words, the first metal nitride layer 351 may have a constant thickness on the inner surface of the through holes.

According to an embodiment, the first metal nitride layer 351 may include a conductive material. For example, the first metal nitride layer 351 may include at least one of a titanium nitride layer (TiN), a tantalum nitride layer (TaN), a tungsten nitride layer (WN), a nickel nitride layer (NiN), a cobalt nitride layer (CoN), and a platinum nitride layer (PtN).

According to an embodiment, the first metal pattern 352 may be positioned on the first metal nitride layer 351. According to an embodiment, the first metal pattern 352 may fill the through holes of the first support substrate 320. According to an embodiment, the first metal pattern 352 may include a different conductive material than the first metal nitride layer 351. For example, the first metal pattern 352 may include a metal such as tungsten, molybdenum, cobalt, etc.

According to an embodiment, the first through-via 350 may connect between at least a portion of the upper wires 212 and the first bumps 200 described below.

According to an embodiment, a plurality of first bumps 200 may be positioned on a first support substrate 320. A plurality of first bumps 200 may be connected to at least a portion of the upper wires 212 through first through-vias 350.

According to an embodiment, the first bump 200 may be, for example, spherical or elliptical in shape on a plane, but is not limited thereto. The first bump 200 may include at least one of, for example, tin (Sn), indium (In), lead (Pb), zinc (Zn), nickel (Ni), gold (Au), silver (Ag), copper (Cu), antimony (Sb), bismuth (Bi), and combinations thereof, but the technical idea of the present disclosure is not limited thereto.

According to an embodiment, the first bump 200 may electrically connect the upper wire structure 210 to an external device. Accordingly, the first bump 200 may provide an electrical signal to the upper wire structure 210 or provide an electrical signal provided from the upper wire structure 210 to an external device. The first bump 200 may apply a signal to at least one of the source/drain patterns SD or the gate electrodes MG_M and MG_S through the upper wires 212 of the upper wire structure 210.

A semiconductor device according to an embodiment may further include a lower contact pattern BCA positioned below at least one of the source/drain patterns SD and a lower wire structure 410 positioned on a second surface 100b of the substrate 100.

According to an embodiment, the lower contact pattern BCA may penetrate the substrate 100 and be electrically connected to at least one of the source/drain patterns SD.

According to an embodiment, the lower contact pattern BCA may be positioned adjacent to the sub-gate electrode MG_S in the first direction D1. According to an embodiment, the lower contact pattern BCA may electrically connect at least some of the lower wires 412 to at least one of the source/drain patterns SD.

For example, the lower contact pattern BCA may include at least one of a metal, a metal alloy, a conductive metal nitride, a conductive metal carbide, a conductive metal oxide, a conductive metal carbonitride, and a two-dimensional (2D) material. The metal may include at least one of titanium (Ti), tantalum (Ta), tungsten (W), nickel (Ni), cobalt (Co), and platinum (Pt). The conductive metal nitride may include at least one of titanium nitride (TiN), tantalum nitride (TaN), tungsten nitride (WN), nickel nitride (NiN), cobalt nitride (CoN), and platinum nitride (PtN).

According to an embodiment, the lower wire structure 410 may include a lower insulating layer 411, lower wires 412, and lower vias. The lower wires 412 and lower vias may include a metal (e.g., copper).

According to an embodiment, a lower insulating layer 411 may be placed between the lower wires 412 and the lower vias to insulate them. The lower insulating layer 411 may cover the substrate 100. The lower wires 412 and lower vias may be positioned within the lower insulating layer 411.

For example, the lower insulating layer 411 may include at least one of silicon oxide (SiOx), silicon nitride (SiNx), silicon oxynitride (SiON), or low-k dielectric layers.

According to an embodiment, at least some of the lower wires 412 may be electrically connected to at least one of the source/drain patterns SD. According to an embodiment, an electrical signal or power voltage supplied from the outside may be provided to the source/drain pattern SD through the lower wires 412 and the lower contact pattern BCA connected to the lower wires 412.

According to an embodiment, a plurality of second bumps 400 may be positioned on the lower wire structure 410. A plurality of second bumps 400 may be connected to at least some of the lower wires 412.

According to an embodiment, the second bump 400 may be, for example, spherical or elliptical in shape on a plane, but is not limited thereto. The second bump 400 may include at least one of, for example, tin (Sn), indium (In), lead (Pb), zinc (Zn), nickel (Ni), gold (Au), silver (Ag), copper (Cu), antimony (Sb), bismuth (Bi), and combinations thereof, but the technical idea of the present disclosure is not limited thereto.

According to an embodiment, the second bump 400 may apply power to the lower wire structure 410. The second bump 400 may apply power to at least one of the source/drain patterns SD or the gate electrodes MG_M and MG_S through the lower wires 412 of the lower wire structure 410.

As described above, since the semiconductor device according to the present disclosure has a structure in which a plurality of first bumps 200 are positioned on an upper wire structure 210 and a plurality of second bumps 400 are positioned on a lower wire structure 410, it may be easy to analyze a defect in the semiconductor device using a laser-based optical method. In other words, by arranging the first bump 200 for applying a signal to the device and the second bump 400 for applying power to the device separately above and below, additional components required to apply a signal or power to the device when the first bump 200 and the second bump 400 are arranged on one surface may be omitted. Accordingly, the accuracy of defect cause analysis may be increased by simplifying the structure of semiconductor devices.

In addition, as described above, the semiconductor device according to the present disclosure may improve the stability of the manufacturing process of the semiconductor device described below by including the first support substrate 320 between the upper wire structure 210 and the plurality of first bumps 200.

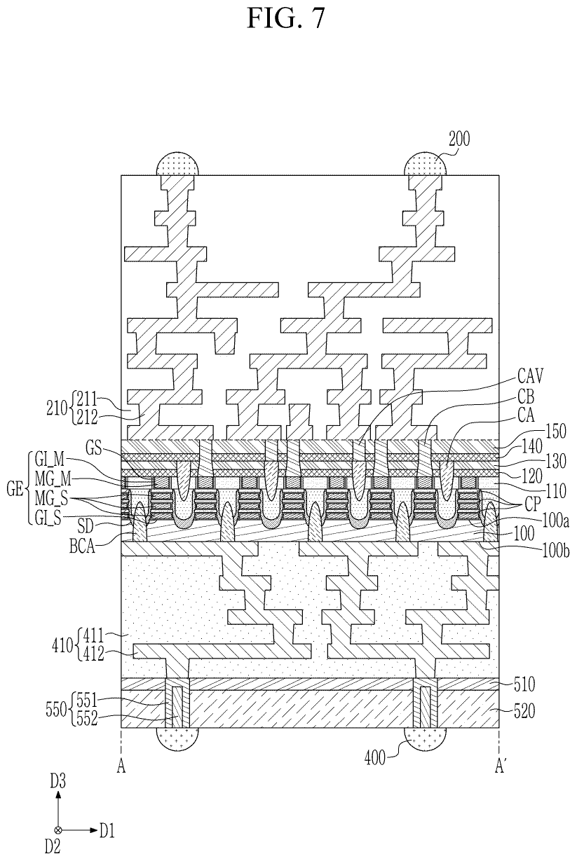

FIG. 7 is a cross-sectional view taken along line A-A′ of FIG. 5 according to an embodiment.

The semiconductor device illustrated in FIG. 7 may include components similar to or identical to the semiconductor device described with reference to FIG. 6. However, the semiconductor device in this embodiment is different from that illustrated in FIG. 6 in that the first adhesive layer 310 and the first support substrate 320 are not positioned on the upper wire structure 210, but the second adhesive layer 510 and the second support substrate 520 are positioned on the lower wire structure 410. Here, any overlapping content with that described above in FIG. 6 will be briefly explained or omitted, and the differences will be mainly explained.

Referring to FIG. 7, a semiconductor device according to an embodiment may further include an upper wire structure 210 positioned on a first surface 100a of a substrate 100, a plurality of first bumps 200 positioned on the upper wire structure 210, a lower wire structure 410 positioned on a second surface 100b of the substrate 100, a second adhesive layer 510 positioned on the lower wire structure 410, a second support substrate 520 positioned on the second adhesive layer 510, a second through-via 550 penetrating the second support substrate 520, and a plurality of second bumps 400 connected to the second through-via 550 on the second support substrate 520.

According to an embodiment, a plurality of first bumps 200 may be positioned on an upper surface of the upper wire structure 210. A plurality of first bumps 200 may be connected to at least a portion of the upper wires 212. For example, a plurality of first bumps 200 may be in contact with at least some of the upper wires 212. In other words, no other components may be interposed between the plurality of first bumps 200 and the upper wires 212.

According to an embodiment, the first bump 200 may apply a signal to the upper wire structure 210. The first bump 200 may apply a signal to at least one of the source/drain patterns SD or the gate electrodes MG_M and MG_S through the upper wires 212 of the upper wire structure 210.

According to an embodiment, a second adhesive layer 510 and a second support substrate 520 may be positioned on the lower wire structure 410.

According to an embodiment, the second adhesive layer 510 may be positioned between the lower wire structure 410 and the second support substrate 520. According to an embodiment, the second support substrate 520 may be bonded to the lower wire structure 410 by a second adhesive layer 510. For example, the second adhesive layer 510 may include SiCN, AlN, tetraethylorthosilicate (TEOS), or a combination thereof.

According to an embodiment, a second support substrate 520 including one side and the other side facing each other may be positioned on the second adhesive layer 510. A second adhesive layer 510 may be positioned on one surface of the second support substrate 520, and a plurality of second bumps 400 may be positioned on the other surface of the second support substrate 520. According to an embodiment, the second support substrate 520 may have through holes opening in a third direction D3. In other words, the through holes may extend in the third direction D3 from the bottom to the top of the second support substrate 520. According to an embodiment, a second through-via 550 described below may be inserted into the through-holes.

For example, the second support substrate 520 may include a silicon, germanium, silicon-germanium, gallium-arsenide (GaAs), glass, plastic, ceramic substrate, or the like. For example, the second support substrate 520 may be formed of a silicon substrate or a glass substrate.

According to an embodiment, the second through-via 550 may penetrate the second support substrate 520 and the second adhesive layer 510. Specifically, the second through-via 550 may pass through the second support substrate 520 and the second adhesive layer 510 to be connected to at least some of the lower wires 412.

According to an embodiment, the second through-via 550 may include a second metal pattern 552 penetrating the second support substrate 520 and a second metal nitride layer 551 surrounding the sidewalls and upper surface of the second metal pattern 552.

According to an embodiment, the second metal nitride layer 551 may be conformally positioned on the inner surface of the through holes of the second support substrate 520. In other words, the second metal nitride layer 551 may have a constant thickness on the inner surface of the through holes.

According to an embodiment, the second metal nitride layer 551 may include a conductive material. For example, the second metal nitride layer 551 may include at least one of a titanium nitride (TiN) layer, a tantalum nitride (TaN) layer, a tungsten nitride (WN) layer, a nickel nitride (NiN) layer, a cobalt nitride (CoN) layer, and a platinum nitride (PtN) layer.

According to an embodiment, the second metal pattern 552 may be positioned on the second metal nitride layer 551. According to an embodiment, the second metal pattern 552 may fill the through holes of the second support substrate 520. According to an embodiment, the second metal pattern 552 may include a different conductive material from the second metal nitride layer 551. For example, the second metal pattern 552 may include a metal such as tungsten, molybdenum, cobalt, etc.

According to an embodiment, the second through-via 550 may connect between at least a portion of the lower wires 412 and the second bumps 400.

According to an embodiment, a plurality of second bumps 400 may be positioned on a second support substrate 520. A plurality of second bumps 400 may be connected to at least a portion of the lower wires 412 through second through-vias 550.

According to an embodiment, the second bump 400 may apply power to the lower wire structure 410 through the second through-via 550. The second bump 400 may apply power to at least one of the source/drain patterns SD or the gate electrodes MG_M and MG_S through the lower wires 412 of the lower wire structure 410.

As described above, the semiconductor device according to the present disclosure may improve the stability of the manufacturing process of the semiconductor device described below by including a second support substrate 520 between the lower wire structure 410 and the plurality of second bumps 400.

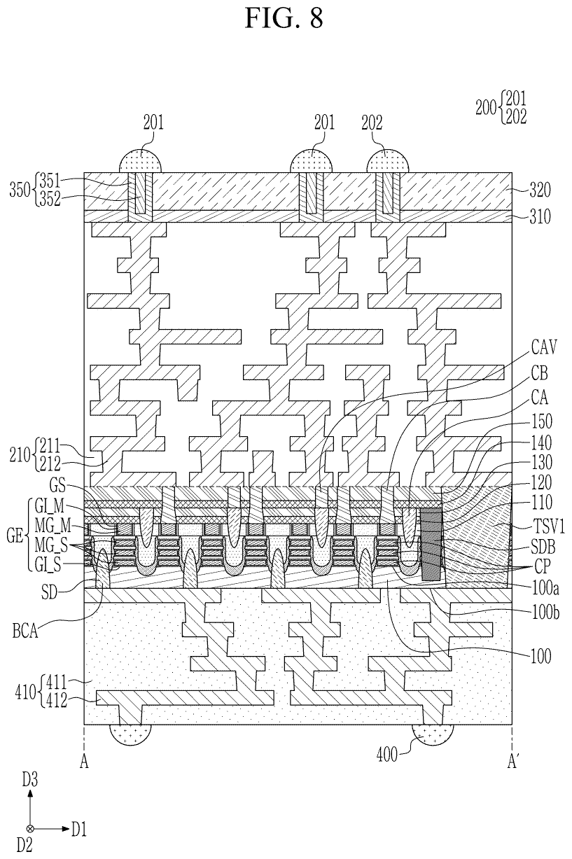

FIG. 8 is a cross-sectional view taken along line A-A′ of FIG. 5 according to an embodiment.

The semiconductor device illustrated in FIG. 8 may include components similar to or identical to the semiconductor device described with reference to FIG. 6. However, the semiconductor device in this embodiment is different from that illustrated in FIG. 6 in that at least some of the first bumps 200 apply a signal to at least one of the source/drain patterns SD and the gate electrodes MG_M and MG_S, and some other of the first bumps 200 apply power to at least one of the source/drain patterns SD and the gate electrodes MG_M and MG_S. Here, any overlapping content with that described above in FIG. 6 will be briefly explained or omitted, and the differences will be mainly explained.

According to an embodiment, the semiconductor device may include a first adhesive layer 310 positioned on an upper surface of an upper wire structure 210, a first support substrate 320 positioned on the first adhesive layer 310, a first through-via 350 penetrating the first support substrate 320, a plurality of first bumps 200 connected to the first through-via 350, and a plurality of second bumps 400 positioned on a lower wire structure 410.

According to an embodiment, at least some of the plurality of first bumps 200 may apply signals to the upper wire structure 210, and some other of the plurality of first bumps 200 may apply power to the upper wire structure 210. For example, the plurality of first bumps 200 may include a first signal bump 201 that applies a signal to the upper wire structure 210 and a first power bump 202 that applies power to the upper wire structure 210. The number of first signal bumps 201 may be greater than the number of first power bumps 202. For example, the first signal bump 201 may be plural and the first power bump 202 may be single, but is not limited thereto.

According to an embodiment, the semiconductor device may further include a first through-electrode TSV1 connecting the upper wires 212 to the lower wires 412 and a device isolation layer SDB positioned adjacent to the first through-electrode TSV1.

According to an embodiment, a first adhesive layer 310 may be positioned on the upper wire structure 210. According to an embodiment, a first support substrate 320 may be positioned on a first adhesive layer 310, and the first support substrate 320 may be bonded to the upper wire structure 210 by the first adhesive layer 310.

According to an embodiment, the first through-via 350 may penetrate the first support substrate 320 and the first adhesive layer 310. Specifically, the first through-via 350 may pass through the first support substrate 320 and the first adhesive layer 310 to be connected to at least some of the upper wires 212.

According to an embodiment, the first through-via 350 may connect between at least a portion of the upper wires 212 and the first bumps 200. According to an embodiment, a portion of the first through-via 350 may connect at least a portion of the first signal bump 201 and the upper wires 212. According to an embodiment, another portion of the first through-via 350 may connect at least a portion of the first power bump 202 and the upper wires 212.

Unlike that illustrated in FIG. 8, according to some embodiments, instead of the first adhesive layer 310, the first through-via 350, and the first support substrate 320 being positioned between the upper wire structure 210 and the plurality of first bumps 200, the second adhesive layer 510, the second through-via 550, and the second support substrate 520 described above with reference to FIG. 7 may be positioned between the lower wire structure 410 and the plurality of second bumps 400.

According to an embodiment, a plurality of first bumps 200 may be positioned on a first support substrate 320.

According to an embodiment, the first signal bump 201 may electrically connect the upper wire structure 210 to an external device. Accordingly, the first signal bump 201 may provide an electrical signal to the upper wire structure 210 or provide an electrical signal provided from the upper wire structure 210 to an external device. The first signal bump 201 may apply a signal to at least one of the source/drain patterns SD or the gate electrodes MG_M and MG_S through the upper wires 212 of the upper wire structure 210.

According to an embodiment, the first through-electrode TSV1 extends in the third direction D3 and may provide an electrical path connecting the first bumps 200 and the second bumps 400.

According to an embodiment, the first power bump 202 may supply (or apply) power to the device through the first through-electrode TSV1. For example, the first power bump 202 may supply (or apply) power to the device through the lower wire structure 410 via the first through-electrode TSV1. The first power bump 202 may supply power to at least one of the source/drain patterns SD and the gate electrodes MG_M and MG_S through the first through-electrode TSV1. The first through-electrode TSV1 may also be used as a ground electrode.

Although not shown, the first through-electrode TSV1 may include a conductive plug and a barrier layer surrounding it. The conductive plug may include a metallic material, such as tungsten (W), titanium (Ti), aluminum (Al), or copper (Cu). For example, the barrier layer may include titanium (Ti), titanium nitride (TiN), tantalum (Ta), or tantalum nitride (TaN).

According to an embodiment, a device isolation layer SDB may be positioned on the side of the first through-electrode TSV1. For example, the device isolation layer SDB may include an insulating material such as silicon oxide, silicon nitride, or silicon oxynitride.

According to an embodiment, a plurality of second bumps 400 may be positioned on the lower wire structure 410. A plurality of second bumps 400 may be connected to at least some of the lower wires 412.

According to an embodiment, the second bump 400 may apply power to the lower wire structure 410. The second bump 400 may apply power to at least one of the source/drain patterns SD or the gate electrodes MG_M and MG_S through the lower wires 412 of the lower wire structure 410.

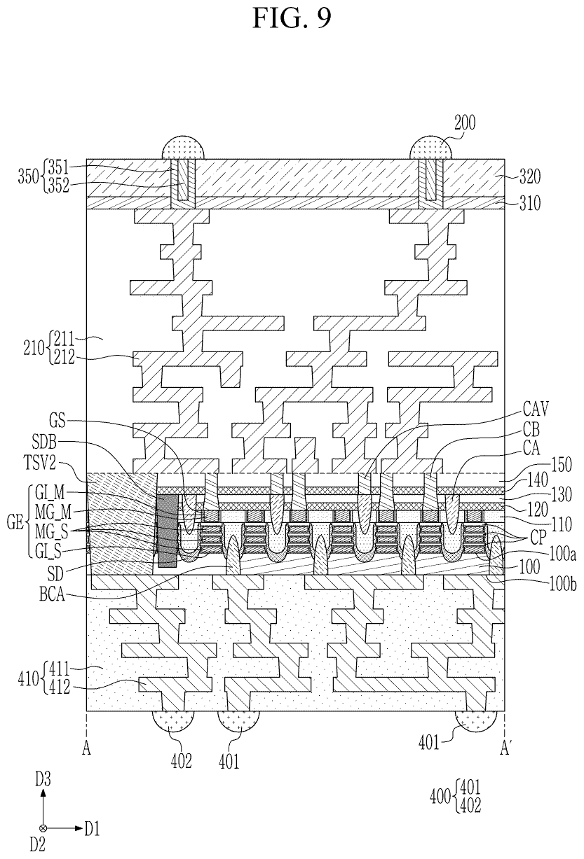

FIG. 9 is a cross-sectional view taken along line A-A′ of FIG. 5 according to an embodiment.

The semiconductor device illustrated in FIG. 9 may include components similar to or identical to the semiconductor device described with reference to FIG. 6. However, the semiconductor device in this embodiment, unlike that illustrated in FIG. 6, has a structure in which at least some of the second bumps 400 apply power to at least one of the source/drain patterns SD and the gate electrodes MG_M and MG_S, and some other of the second bumps 400 apply a signal to at least one of the source/drain patterns SD and the gate electrodes MG_M and MG_S. Here, any overlapping content with that described above in FIG. 6 will be briefly explained or omitted, and the differences will be mainly explained.

According to an embodiment, the semiconductor device may include a first adhesive layer 310 positioned on an upper wire structure 210, a first support substrate 320 positioned on the first adhesive layer 310, a first through-via 350 penetrating the first support substrate 320, a plurality of first bumps 200 connected to the first through-via 350, and a plurality of second bumps 400 positioned on a lower wire structure 410.

According to an embodiment, at least some of the plurality of second bumps 400 may apply power to the lower wire structure 410, and some other of the plurality of second bumps 400 may apply signals to the lower wire structure 410. For example, the plurality of second bumps 400 may include a second power bump 401 that applies power to the lower wire structure 410 and a second signal bump 402 that applies a signal to the lower wire structure 410. The number of second power bumps 401 may be greater than the number of second signal bumps 402. For example, the second power bump 401 may be plural and the second signal bump 402 may be single, but is not limited thereto.

According to an embodiment, the semiconductor device may further include a second through-electrode TSV2 connecting the lower wires 412 to the upper wires 212 and a device isolation layer SDB positioned adjacent to the second through-electrode TSV2.

According to an embodiment, a first adhesive layer 310 may be positioned on the upper wire structure 210. According to an embodiment, a first support substrate 320 may be positioned on a first adhesive layer 310, and the first support substrate 320 may be bonded to the upper wire structure 210 by the first adhesive layer 310.

According to an embodiment, the first through-via 350 may penetrate the first support substrate 320 and the first adhesive layer 310. Specifically, the first through-via 350 may pass through the first support substrate 320 and the first adhesive layer 310 to be connected to at least some of the upper wires 212.

According to an embodiment, the first through-via 350 may connect between at least a portion of the upper wires 212 and the first bumps 200.

Unlike that illustrated in FIG. 9, according to some embodiments, instead of the first adhesive layer 310, the first through-via 350, and the first support substrate 320 being positioned between the upper wire structure 210 and the plurality of first bumps 200, the second adhesive layer 510, the second through-via 550, and the second support substrate 520 described above with reference to FIG. 7 may be positioned between the lower wire structure 410 and the plurality of second bumps 400.

According to an embodiment, a plurality of first bumps 200 may be positioned on a first support substrate 320. According to an embodiment, the first bump 200 may apply a signal to the upper wire structure 210. The first bump 200 may apply a signal to at least one of the source/drain patterns SD or the gate electrodes MG_M and MG_S through the upper wires 212 of the upper wire structure 210.

According to an embodiment, a plurality of second bumps 400 may be positioned on the lower wire structure 410.

According to an embodiment, the second power bump 401 may supply power to the device through the lower wire structure 410. The second power bump 401 may apply power to at least one of the source/drain patterns SD and the gate electrodes MG_M and MG_S through the lower wire structure 410.

According to an embodiment, the second through-electrode TSV2 extends in the third direction D3 and may provide an electrical path connecting the first bumps 200 and the second bumps 400.

According to an embodiment, the second signal bump 402 may apply a signal to the device through the second through-electrode TSV2. For example, the second signal bump 402 may apply a signal to the device through the upper wire structure 210 via the second through-electrode TSV2. The second signal bump 402 may apply a signal to at least one of the source/drain patterns SD and the gate electrodes MG_M and MG_S through the second through-electrode TSV2. The second through-electrode TSV2 may also be used as a ground electrode.

Although not shown, the second through-electrode TSV2 may include a conductive plug and a barrier layer surrounding it. The conductive plug may include a metallic material, such as tungsten (W), titanium (Ti), aluminum (Al), or copper (Cu). For example, the barrier layer may include titanium (Ti), titanium nitride (TiN), tantalum (Ta), or tantalum nitride (TaN).

According to an embodiment, a device isolation layer SDB may be positioned on the side of the second through-electrode TSV2. For example, the device isolation layer SDB may include an insulating material such as silicon oxide, silicon nitride, or silicon oxynitride.

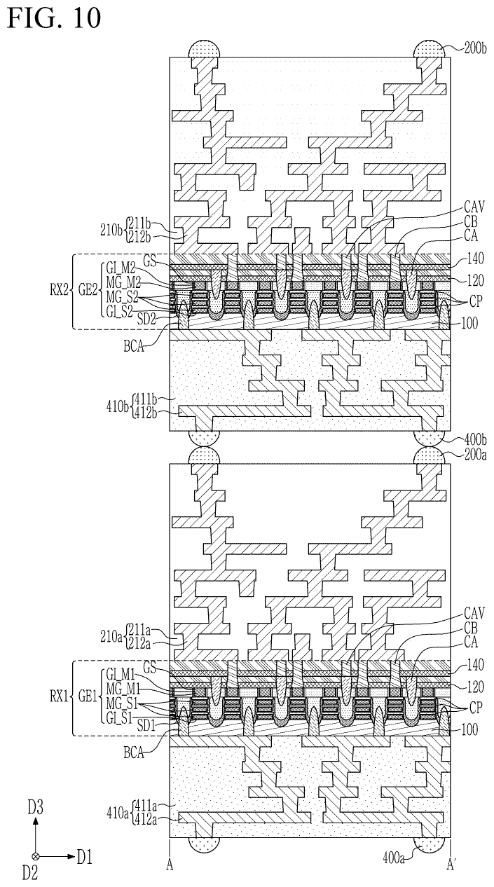

FIG. 10 is a cross-sectional view taken along line A-A′ of FIG. 5 according to an embodiment.

The semiconductor device illustrated in FIG. 10 may include components similar to or identical to the semiconductor device described with reference to FIG. 6 or FIG. 7. However, the semiconductor device in this embodiment has a structure that does not include the first support substrate 320 and the second support substrate 520, unlike that illustrated in FIG. 6 or FIG. 7. Here, any content that overlaps with that described above in FIG. 6 or FIG. 7 will be briefly explained or omitted, and the differences will be mainly explained.

According to an embodiment, the semiconductor device may include a plurality of first upper bumps 200a and a first upper wire structure 210a connected to signal lines, a plurality of first lower bumps 400a and a first lower wire structure 410a connected to power lines, and a first device RX1 positioned between the first upper wire structure 210a and the first lower wire structure 410a.

According to an embodiment, the first upper wire structure 210a may include first upper wires 212a and a first upper insulating layer 211a that insulates them. According to an embodiment, the first lower wire structure 410a may include first lower wires 412a and a first lower insulating layer 411a that insulates them.

According to an embodiment, the first device RX1 may include a plurality of first gate structures GE1 and first source/drain patterns SD1 positioned between the plurality of first gate structures GE1. Each of the plurality of first gate structures GE1 may include a first main gate structure MG_M1 and GI_M1 and a plurality of first sub-gate structures MG_S1 and GI_S1. The first main gate structure MG_M1 and GI_M1 may include a first main gate electrode MG_M1 and a first main gate insulating layer GI_M1. The first sub-gate structure MG_S1 and GI_S1 may include a first sub-gate electrode MG_S1 and a first sub-gate insulating layer GI_S1.

Although not explicitly shown in FIG. 10, a plurality of first upper bumps 200a and a plurality of first lower bumps 400a may be positioned along the edge of the device region where the first device RX1 is positioned.

According to an embodiment, the plurality of first upper bumps 200a may apply a signal to at least one of the plurality of first gate structures GE1 or at least one of the first source/drain patterns SD1. According to an embodiment, a plurality of first lower bumps 400a may apply power to at least one of a plurality of first gate structures GE1 or at least one of first source/drain patterns SD1.

According to an embodiment, the semiconductor device may comprise a plurality of a first upper bump 200a positioned on the plurality of a second lower bump 400b and a second lower wire structure 410b connected to a power line, a plurality of a second upper bump 200b and a second upper wire structure 210b positioned above the second lower wire structure 410b and connected to a signal line, and a second device RX2 positioned between the second upper wire structure 210b and the second lower wire structure 410b.

In FIG. 10, two devices are illustrated as being stacked in the third direction D3, but this is not limited thereto, and the number of devices stacked may vary. For example, three or more devices may be stacked in the third direction D3.

According to an embodiment, the second upper wire structure 210b may include second upper wires 212b and a second upper insulating layer 211b that insulates them. According to an embodiment, the second lower wire structure 410b may include second lower wires 412b and a second lower insulating layer 411b that insulates them.

According to an embodiment, the second device RX2 may include a plurality of second gate structures GE2 and second source/drain patterns SD2 positioned between the plurality of second gate structures GE2. Each of the plurality of second gate structures GE2 may include a second main gate structure MG_M2 and GI_M2 and a plurality of second sub-gate structures MG_S2 and GI_S2. The second main gate structure MG_M2 and GI_M2 may include a second main gate electrode MG_M2 and a second main gate insulating layer GI_M2. The second sub-gate structure MG_S2 and GI_S2 may include a second sub-gate electrode MG_S2 and a second sub-gate insulating layer GI_S2.

Although not explicitly shown in FIG. 10, a plurality of second upper bump 200b and a plurality of second lower bump 400b may be positioned along the edge of the device region where the second device RX2 is positioned.

According to an embodiment, a plurality of second upper bumps 200b may apply a signal to at least one of a plurality of second gate structures GE2 or at least one of second source/drain patterns SD2. According to an embodiment, a plurality of second lower bumps 400b may apply power to at least one of a plurality of second gate structures GE2 or at least one of second source/drain patterns SD2.

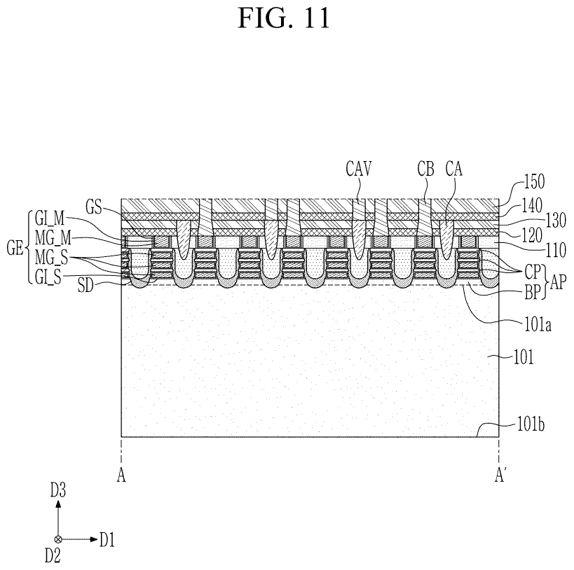

FIG. 11 to FIG. 17 are cross-sectional views showing a method of manufacturing a semiconductor device according to an embodiment of the process sequence. FIG. 11 to FIG. 17 are drawings corresponding to the cross-sectional views taken along line A-A′ of FIG. 5.

Referring to FIG. 11, an active pattern AP, a source/drain pattern SD, a gate structure GE, a gate spacer GS, first to fifth interlayer insulating layers 110, 120, 130, 140 and 150, a contact pattern CA, a contact via CAV, and a gate contact pattern CB may be formed on a silicon substrate 101.

First, a silicon substrate 101 having a third surface 101a and a fourth surface 101b facing each other may be provided. The third surface 101a and the fourth surface 101b of the silicon substrate 101 may be formed as planes parallel to the first direction D1 and the second direction D2 intersecting the first direction D1. For example, the third surface 101a of the silicon substrate 101 may be the top surface, and the fourth surface 101b may be the bottom surface. The upper surface of the silicon substrate 101 is a surface opposite to the bottom surface of the silicon substrate 101 in the third direction D3. The third direction D3 may be a direction perpendicular to the first direction D1 and the second direction D2. The bottom surface of the silicon substrate 101 may be referred to as the back side of the silicon substrate 101.

According to an embodiment, sacrificial layers and active layers are formed alternately stacked on a third surface 101a of a silicon substrate 101. The sacrificial layers may contain silicon (Si), germanium (Ge), or silicon-germanium (SiGe), and the active layers may contain silicon (Si), germanium (Ge), or silicon-germanium (SiGe). For example, the sacrificial layers may contain silicon germanium (SiGe), and the active layers may contain silicon (Si).

Mask patterns may be individually formed on silicon substrate 101. The mask pattern may have a line shape or a bar shape extending in the first direction D1.

By performing a patterning process using mask patterns as an etching mask, a trench defining an active pattern AP may be formed. Accordingly, an active pattern AP may be formed in the logic cell region.

An active pattern AP may include sacrificial layers and active layers alternately stacked on top of it.

Afterwards, the sacrificial layers on top of the active pattern AP may be exposed. For example, mask patterns may be formed on the active pattern AP of the logic cell region, and sacrificial layers may be exposed by performing a patterning process using the mask patterns as an etching mask.

Next, a sacrificial layer may be formed on the front surface of the silicon substrate 101, a hard mask pattern may be formed on the sacrificial layer, and the sacrificial layer may be patterned using the hard mask pattern as an etching mask to form a sacrificial pattern.

For example, the sacrificial pattern may be formed in a line shape or a bar shape extending in the second direction D2. The sacrificial patterns may be arranged along the first direction D1 at a predetermined pitch. The sacrificial layer may contain polysilicon.

Next, a pair of gate spacers GS may be formed on both sidewallss of each of the sacrificial patterns.

For example, a gate spacer layer may be conformally formed on the entire surface of a silicon substrate 101, and the gate spacer layer may be anisotropically etched to form a gate spacer Gs.

For example, the gate spacer layer may include SiCN, SiCON, SiN, or a combination thereof. Additionally, the gate spacer layer may be formed of a multi-layer including SiCN, SiCON, SiN, or a combination thereof.

Next, the active pattern AP may be patterned to form recesses, and source/drain patterns SD may be formed within the recesses.

For example, a first selective epitaxial growth (SEG) process may be performed using the interior wall of the recess as a seed layer to form the first source/drain layer. The first source/drain layer may be grown using the channel patterns CP and lower patterns BP exposed by the recess as seeds. For example, the first SEG process may include a chemical vapor deposition (Chemical Vapor Deposition: CVD) process or a molecular beam epitaxy (Molecular Beam Epitaxy: MBE) process.

A second source/drain layer may be formed by performing a second SEG process on the first source/drain layer. A second source/drain layer may be formed to completely fill the recess. The second source/drain layer may contain a relatively high concentration of germanium (Ge).

The first source/drain layer and the second source/drain layer may form a source/drain pattern SD. During the first and second SEG processes, impurities may be implanted in-situ. As another example, an impurity may be implanted into the source/drain pattern SD after the source/drain pattern SD is formed. The source/drain pattern SD may be doped to have either a first conductivity type (e.g., p-type) or a second conductivity type (e.g., n-type).

Next, the first interlayer insulating layer 110 may be formed, and after removing the sacrificial layers, the gate electrode MG_M and MG_S may be formed.

Specifically, a first interlayer insulating layer 110 is formed covering a source/drain pattern SD, a hard mask pattern, and a gate spacer GS. For example, the first interlayer insulating layer 110 may include a silicon oxide layer.

Next, the first interlayer insulating layer 110 may be planarized until the top surface of the sacrificial pattern is exposed. Planarization of the first interlayer insulating layer 110 may be performed using a chemical mechanical polishing (CMP) process. During the planarization process, all hard mask patterns may be removed. As a result, the upper surface of the first interlayer insulating layer 110 may be positioned at substantially the same level as the upper surface of the sacrificial pattern and the upper surface of the gate spacer GS.

Next, the exposed sacrificial pattern may be selectively removed. By removing the sacrificial pattern, first empty spaces may be formed to expose the channel pattern CP. First, through the empty space, sacrificial layers between channel patterns CP may be exposed.

Next, sacrificial layers exposed through the first empty space may be selectively removed.

For example, by performing an etching process that selectively etches sacrificial layers, only the sacrificial layers may be removed while leaving the channel patterns CP intact. The etching process may have a high etch rate for silicon-germanium having a relatively high germanium concentration.

Sacrificial layers may be removed during the etching process. The etching process may be, for example, wet etching. The etching material used in the etching process may rapidly remove the sacrificial layer with a relatively high germanium concentration.

By selectively removing the sacrificial layers, only the channel patterns CP remain on the lower pattern BP. Second empty spaces may be formed through regions where sacrificial layers have been removed. The second empty spaces may be positioned between the lower pattern BP and the channel pattern CP positioned at the bottom, and between channel patterns CP.

Next, the gate insulating layer GI_M and GI_S is conformally formed within the first and second empty spaces. Afterwards, the gate electrode MG_M and MG_S may be formed on the gate insulating layer GI_M and GI_S. The gate electrodes MG_M and MG_S may be formed to fill the first and second empty spaces.

After sequentially forming a second interlayer insulating layer 120 and a third interlayer insulating layer 130 on a first interlayer insulating layer 110, a contact pattern CA electrically connected to a source/drain pattern SD may be formed by penetrating the first to third interlayer insulating layers 110, 120, and 130.

Next, a fourth interlayer insulating layer 140 and a fifth interlayer insulating layer 150 are sequentially formed on a third interlayer insulating layer 130, and then a contact via CAV connected to a contact pattern CA through the fourth and fifth interlayer insulating layers 140 and 150, and a gate contact pattern CB connected to a main gate electrode MG_M through the second to fifth interlayer insulating layers 120, 130, 140 and 150 may be formed.

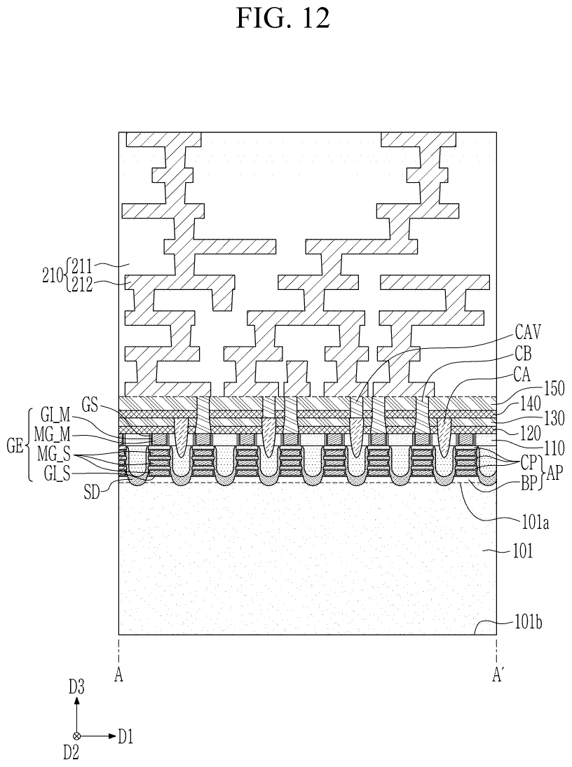

Referring to FIG. 12, an upper wire structure 210 may be formed that is electrically connected to at least one of the source/drain patterns SD through a contact via CAV and a contact pattern CA, and electrically connected to at least one of the gate electrodes MG_M and MG_S through a gate contact pattern CB.

According to an embodiment, an upper insulating layer 211 may be formed on a fifth interlayer insulating layer 150. For example, the upper insulating layer 211 may be formed through a deposition process, such as a chemical vapor deposition (CVD) process or an atomic layer deposition (ALD) process.

According to an embodiment, the upper insulating layer 211 may be patterned to form trenches (not shown). For example, the etching process for patterning the upper insulating layer 211 may be performed by a dry or wet etching method, but is not limited thereto.

According to an embodiment, upper wires 212 and upper vias may be formed within trenches (not shown). Accordingly, an upper wire structure 210 may be formed on the upper surface of the fifth interlayer insulating layer 150.

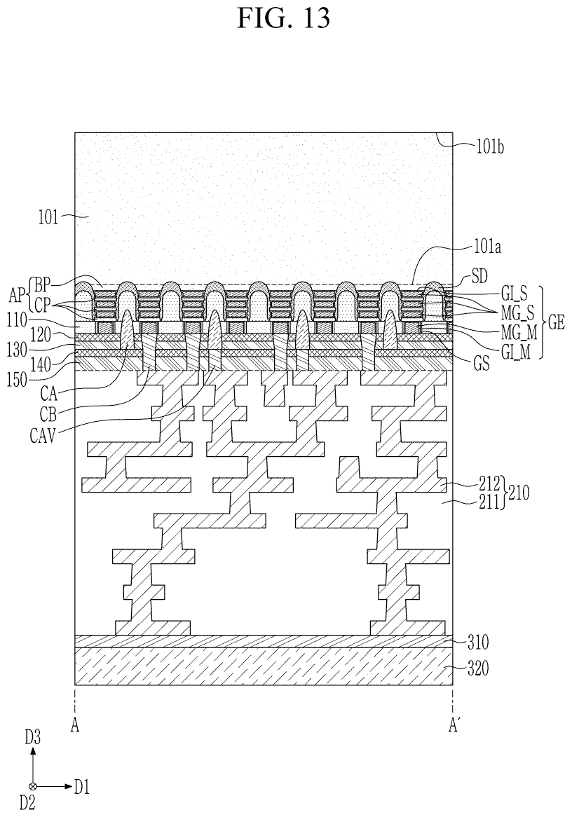

Referring to FIG. 13, a first support substrate 320 may be joined to the upper surface of the upper wire structure 210.

According to an embodiment, a first adhesive layer 310 may be formed on a first support substrate 320. Next, the first support substrate 320 and the upper wire structure 210 may be joined using the first adhesive layer 310. Accordingly, the first adhesive layer 310 may cover the upper wire structure 210. One surface of the first adhesive layer 310 may be in contact with the upper wire structure 210, and the other surface of the first adhesive layer 310 may be in contact with the first support substrate 320.

Next, the silicon substrate 101 may be rotated so that the third surface 101a of the silicon substrate 101 is facing downward. Therefore, the fourth surface 101b, which is the opposite surface of the third surface 101a of the silicon substrate 101, is positioned at the top. In other words, the subsequent process may be performed by positioning the first support substrate 320 below.

The semiconductor device according to the present disclosure may improve the stability of the manufacturing process of the semiconductor device by bonding the upper wire structure 210 and the first support substrate 320 and performing subsequent processes.

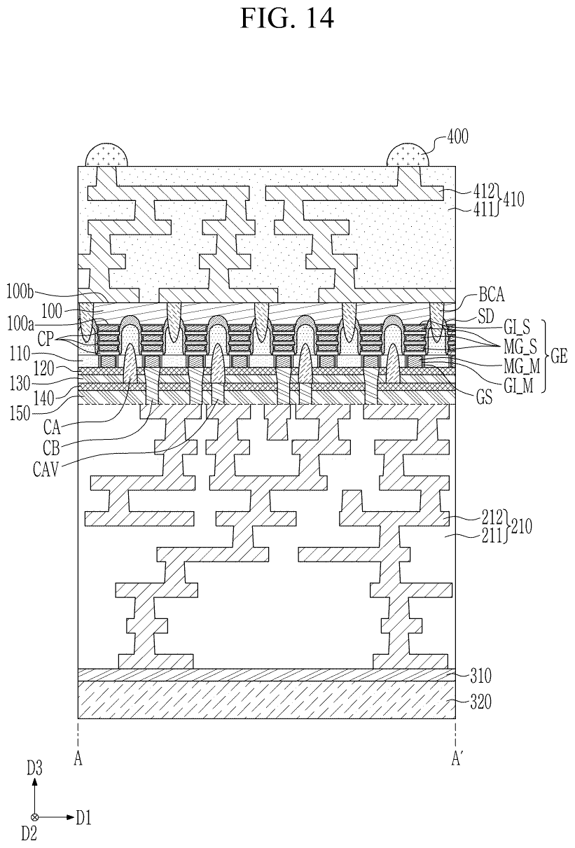

Referring to FIG. 14, the silicon substrate 101 is replaced with the substrate 100, and a lower wire structure 410 and a plurality of second bumps 400 may be formed.

According to an embodiment, a silicon substrate 101 may be made thin by removing a certain portion from the lower surface, and then an additional CMP (chemical mechanical polishing) process may be performed.

Next, the lower pattern BP shown in FIG. 11 to FIG. 13 may be removed until the sub-gate structure MG_S and GI_S is exposed. Specifically, the lower pattern BP may be removed until the sub-gate structure MG_S and GI_S positioned at the lowest position among the plurality of sub-gate structures MG_S and GI_S is exposed.

According to an embodiment, a silicon substrate 101 and a space from which a lower pattern BP has been removed may be filled with an insulating material to form a substrate 100. According to an embodiment, the substrate 100 may be formed to cover the bottom surface of the sub-gate structure MG_S and GI_S and the source/drain pattern SD positioned at the lowest position.

For example, substrate 100 may include at least one of silicon oxide SiO2, silicon nitride (SiN), silicon nitride (SiON), and a low dielectric constant material.

Next, a lower contact pattern BCA electrically connected to the source/drain pattern SD and a lower wire structure body 410 electrically connected to the source/drain pattern SD through the lower contact pattern BCA may be formed.

According to an embodiment, a trench is formed penetrating the substrate 100. Next, a lower contact pattern BCA may be formed within the trench, and a lower insulating layer 411 covering the lower contact pattern BCA and the substrate 100 may be formed. For example, the lower insulating layer 411 may be formed through a deposition process, such as a chemical vapor deposition (CVD) process, or an atomic layer deposition (ALD) process.

According to an embodiment, the lower insulating layer 411 may be patterned to form trenches (not shown). For example, the etching process for patterning the lower insulating layer 411 may be performed by a dry or wet etching method, but is not limited thereto.

According to an embodiment, lower wires 412 and lower vias may be formed within trenches (not shown). Accordingly, a lower wire structure 410 may be formed on the second surface 100b of the substrate 100.

According to an embodiment, a plurality of second bumps 400 connected to at least a portion of the lower wires 412 may be formed on the lower wire structure 410. Although not explicitly shown in FIG. 14, a plurality of second bumps 400 may be positioned along the edge of the device region where the device is positioned. A plurality of second bump 400 may not be positioned in the central region within the device region where the device is positioned. In other words, from a planar perspective looking at the back of the semiconductor device, the arrangement shape of the plurality of second bumps 400 may have a closed shape or a loop shape extending along the edge of the device region.

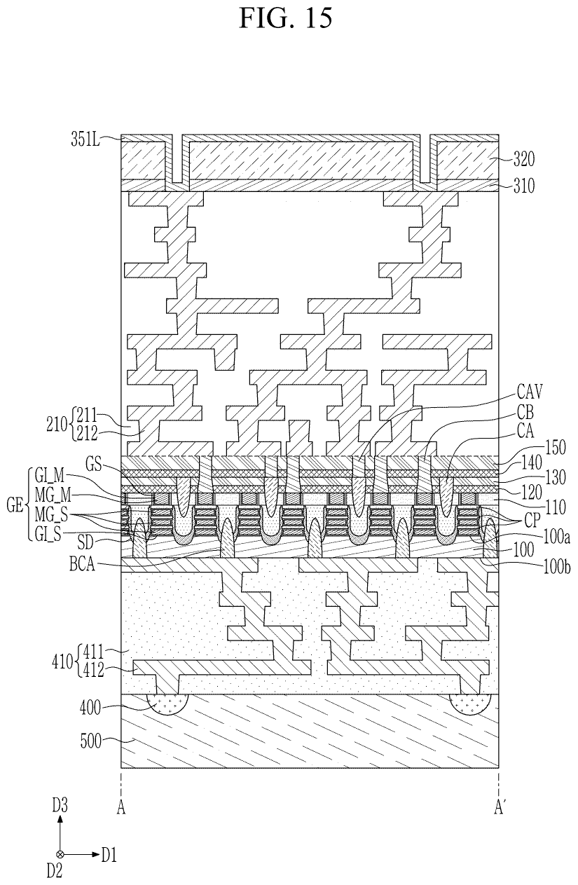

Referring to FIG. 15, a first passivation layer 500 covering a plurality of second bumps 400 may be formed. According to an embodiment, the first passivation layer 500 may cover the bottom surface of each of the side surfaces of a plurality of second bumps 400. According to an embodiment, the first passivation layer 500 may include an organic material. For example, the first passivation layer 500 may include a photoresist.

According to an embodiment, the substrate 100 may be rotated so that the second side 100b of the substrate 100 is facing downward. Accordingly, the first passivation layer 500 may be positioned below, and the first support substrate 320 may be positioned above.

Next, through holes penetrating the first support substrate 320 may be formed, and a first metal nitride material layer 351L may be formed on the inner surface of the through holes. A first metal nitride material layer 351L may be formed on the exposed surface as the through holes are formed. A first metal nitride material layer 351L may be formed on the bottom and inner surfaces of the penetration holes. In other words, the first metal nitride material layer 351L may conformally cover the interior wall of the penetration holes. The first metal nitride material layer 351L is in contact with the upper wires 212, which overlap the through holes and the third direction D3. Additionally, the first metal nitride material layer 351L may be formed on the surface of the first support substrate 320. In other words, the first metal nitride material layer 351L may conformally cover the surface of the first support substrate 320.

According to various embodiments, the first metal nitride material layer 351L may be formed by one of a physical vapor deposition (physical vapor deposition, PVD) process, a chemical vapor deposition (chemical vapor deposition, CVD) process or an atomic layer deposition (atomic layer deposition, ALD) process.

For example, the first metal nitride material layer 351L may include at least one of a titanium nitride (TiN) layer, a tantalum nitride (TaN) layer, a tungsten nitride (WN) layer, a nickel nitride (NiN) layer, a cobalt nitride (CoN) layer, and a platinum nitride (PtN) layer.

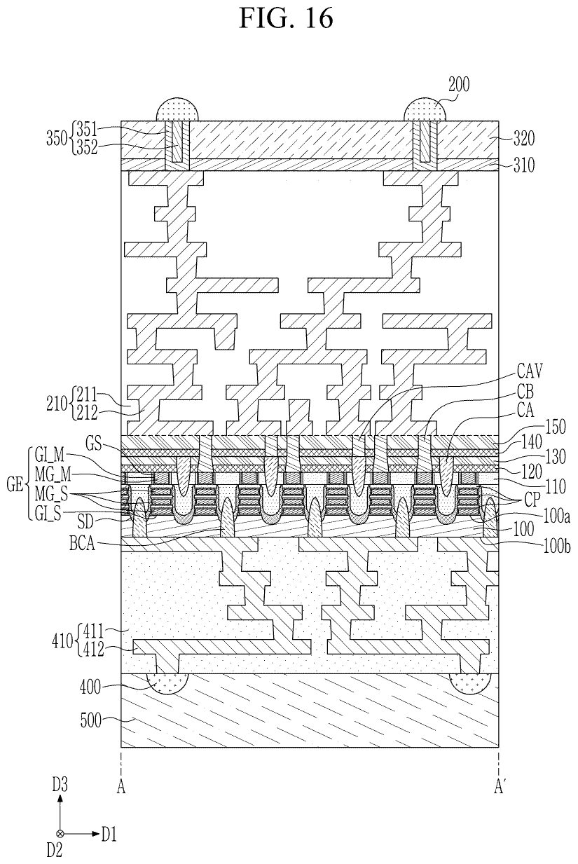

Referring to FIG. 16, a first metal pattern 352 may be formed on the first metal nitride material layer 351L illustrated in FIG. 15.

According to an embodiment, the first metal pattern 352 may be formed by a bottom-up deposition process. Bottom-up deposition processes may be formed through the chemical vapor deposition (CVD) process.

According to an embodiment, the first metal pattern 352 may be formed through a chemical vapor deposition (CVD) process using the first metal nitride material layer 351L as a seed. For example, the deposited material may contain tungsten or a tungsten alloy. However, this is not limited to this and other metals may be used to form the first metal pattern 352. Although not explicitly shown, the first metal pattern 352 may be formed to cover the first metal nitride material layer 351L.

Afterwards, at least a portion of the first metal nitride material layer 351L may be removed through a chemical mechanical polishing (CMP) process. Specifically, a portion of the first metal nitride material layer 351L covering the upper surface of the first support substrate 320 may be removed. At this time, among the first metal pattern 352, a portion covering the first metal nitride material layer 351L on the upper surface of the first support substrate 320 may be removed together.

Through the etching process of this step, the first metal nitride material layer 351L may have a shape that covers the side and bottom surfaces of the first metal pattern 352. In other words, the first metal nitride layer 351 may be formed through the etching process.

Accordingly, a first through-via 350 penetrating the first support substrate 320 may be formed.

According to an embodiment, the first metal pattern 352 may include a metallic material. For example, the first metal pattern 352 may include a metal such as tungsten, molybdenum, cobalt, etc.

According to an embodiment, a plurality of first bumps 200 connected to a first through-via 350 may be formed on a first support substrate 320. Although not explicitly shown in FIG. 16, a plurality of first bumps 200 may be positioned along the edge of the device region where the device is positioned. A plurality of first bump 200 may not be positioned in the central region within the device region where the device is positioned. In other words, from a planar perspective looking at the front of the semiconductor device, the arrangement shape of the plurality of first bumps 200 may have a closed shape or a loop shape extending along the edge of the device region.

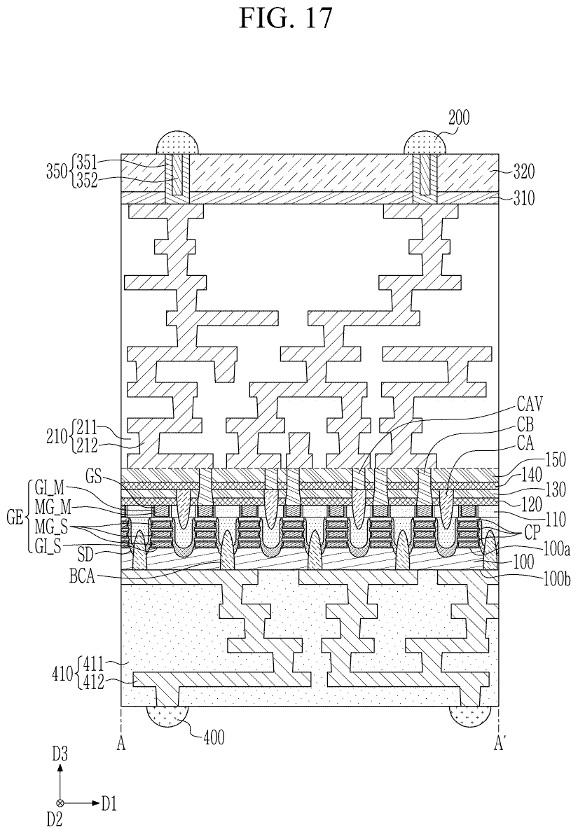

By referring to FIG. 17, the first passivation layer 500 illustrated in FIG. 16 may be removed. Accordingly, as shown in FIG. 6, a structure may be formed in which a first adhesive layer 310 and a first support substrate 320 are positioned on an upper wire structure 210, a plurality of first bumps 200 are positioned on the first support substrate 320, and a plurality of second bumps 400 are positioned on a lower wire structure 410.

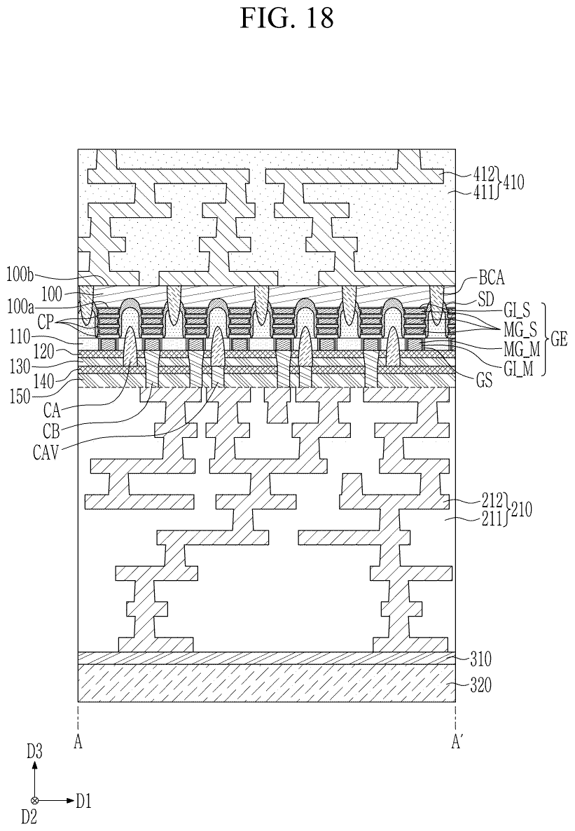

FIG. 18 to FIG. 20 are intermediate drawings illustrating a manufacturing method of a semiconductor device according to some embodiments. For better understanding and ease of description, any content that overlaps with that described above in FIG. 11 to FIG. 13 will be briefly explained or omitted

FIG. 18 to FIG. 20 are drawings corresponding to the cross-sectional views taken along line A-A′ of FIG. 5.

Referring to FIG. 18, the first surface 100a of substrate 100 may be positioned below, and the second surface 100b of substrate 100 may be positioned above. An upper wire structure 210 including upper wires 212 and an upper insulating layer 211, a first adhesive layer 310, and a first support substrate 320 may be sequentially positioned on a first surface 100a of a substrate 100.

A lower wire structure 410 including lower wires 412 and a lower insulating layer 411 may be positioned on the second surface 100b of the substrate 100.

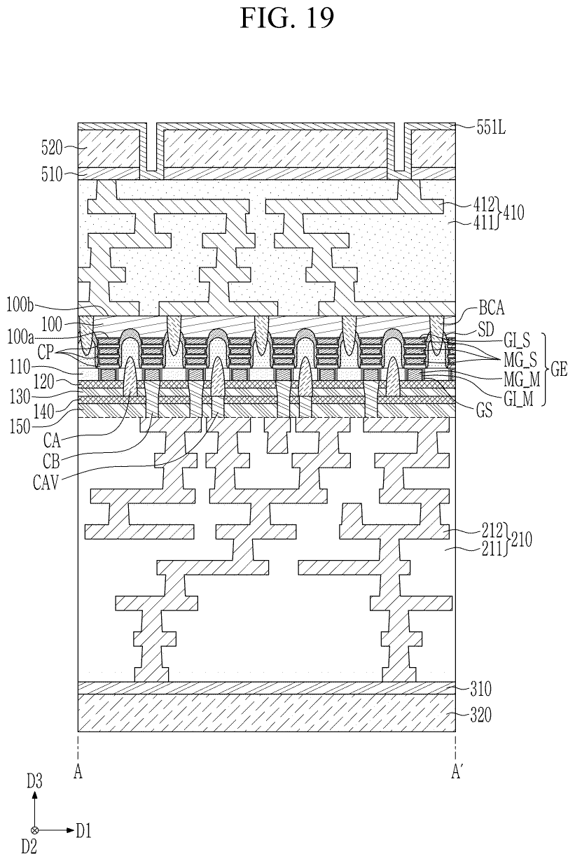

Referring to FIG. 19, a second support substrate 520 may be joined to the lower wire structure 410.

According to an embodiment, a second adhesive layer 510 may be formed on a second support substrate 520. Next, the second support substrate 520 and the lower wire structure 410 may be joined using the second adhesive layer 510. Accordingly, the second adhesive layer 510 may cover the lower wire structure 410. One surface of the second adhesive layer 510 may be in contact with the lower wire structure 410, and the other surface of the second adhesive layer 510 may be in contact with the second support substrate 520.

Next, through holes penetrating the second support substrate 520 may be formed, and a second metal nitride material layer 551L may be formed on the inner surface of the through holes. A second metal nitride material layer 551L may be formed on the exposed surface as the through holes are formed. A second metal nitride material layer 551L may be formed on the bottom and inner surfaces of the penetration holes. In other words, the second metal nitride material layer 551L may conformally cover the interior walls of the penetration holes. The second metal nitride material layer 551L may be in contact with the lower wires 412, which overlap the through holes and the third direction D3. Additionally, a second metal nitride material layer 551L may be formed on the surface of the second support substrate 520. In other words, the second metal nitride material layer 551L may conformally cover the surface of the second support substrate 520.

According to various embodiments, the second metal nitride material layer 551L may be formed by one of a physical vapor deposition (physical vapor deposition, PVD) process, a chemical vapor deposition (chemical vapor deposition, CVD) process or an atomic layer deposition (atomic layer deposition, ALD) process.

For example, the second metal nitride material layer 551L may include at least one of a titanium nitride (TiN) layer, a tantalum nitride (TaN) layer, a tungsten nitride (WN) layer, a nickel nitride (NiN) layer, a cobalt nitride (CoN) layer, and a platinum nitride (PtN) layer.

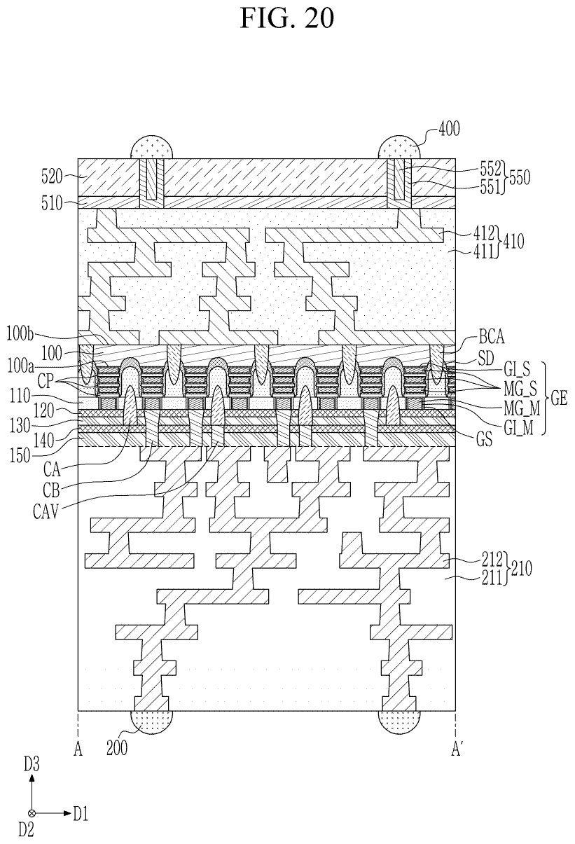

Referring to FIG. 20, a second metal pattern 552 may be formed on the second metal nitride material layer 551L illustrated in FIG. 19.

According to an embodiment, the second metal pattern 552 may be formed by a bottom-up deposition process. Bottom-up deposition processes may be formed through the chemical vapor deposition (CVD) process.

According to an embodiment, the second metal pattern 552 may be formed through a chemical vapor deposition (CVD) process using the second metal nitride material layer 551L as a seed. For example, the deposited material may contain tungsten or a tungsten alloy. However, this is not limited to this and other metals may be used to form the second metal pattern 552. Although not explicitly shown, the second metal pattern 552 may be formed to cover the second metal nitride material layer 551L.

Afterwards, at least a portion of the second metal nitride material layer 551L may be removed through a chemical mechanical polishing (CMP) process. Specifically, a portion of the second metal nitride material layer 551L covering the lower surface of the second support substrate 520 may be removed. At this time, among the second metal pattern 552, a portion covering the second metal nitride material layer 551L on the lower surface of the second support substrate 520 may be removed together.

Through the etching process of this step, the second metal nitride material layer 551L may have a shape that covers the side and upper surfaces of the second metal pattern 552. In other words, the second metal nitride layer 551 may be formed through the etching process.

Accordingly, a second through-via 550 penetrating the second support substrate 520 may be formed.

According to an embodiment, the second metal pattern 552 may include a metallic material. For example, the second metal pattern 552 may include a metal such as tungsten, molybdenum, cobalt, etc.

According to an embodiment, a plurality of second bumps 400 connected to a second through-via 550 may be formed on a second support substrate 520. Although not explicitly shown in FIG. 20, a plurality of second bumps 400 may be positioned along the edge of the device region where the device is positioned. A plurality of second bump 400 may not be positioned in the central region within the device region where the device is positioned. In other words, from a planar perspective looking at the back of the semiconductor device, the arrangement shape of the plurality of second bumps 400 may have a closed shape or a loop shape extending along the edge of the device region.

According to an embodiment, the first adhesive layer 310 and the first support substrate 320 illustrated in FIG. 19 may be removed. Next, a plurality of first bumps 200 connected to at least a portion of the upper wires 212 may be formed on the upper wire structure 210. Although not explicitly shown in FIG. 20, a plurality of first bumps 200 may be positioned along the edge of the device region where the device is positioned. A plurality of first bump 200 may not be positioned in the central region within the device region where the device is positioned. In other words, from a planar perspective looking at the front of the semiconductor device, the arrangement shape of the plurality of first bumps 200 may have a closed shape or a loop shape extending along the edge of the device region.

Accordingly, as shown in FIG. 7, a structure may be formed in which a second adhesive layer 510 and a second support substrate 520 are positioned on a lower wire structure 410, a plurality of second bumps 400 are positioned on the second support substrate 520, and a plurality of first bumps 200 are positioned on an upper wire structure 210.

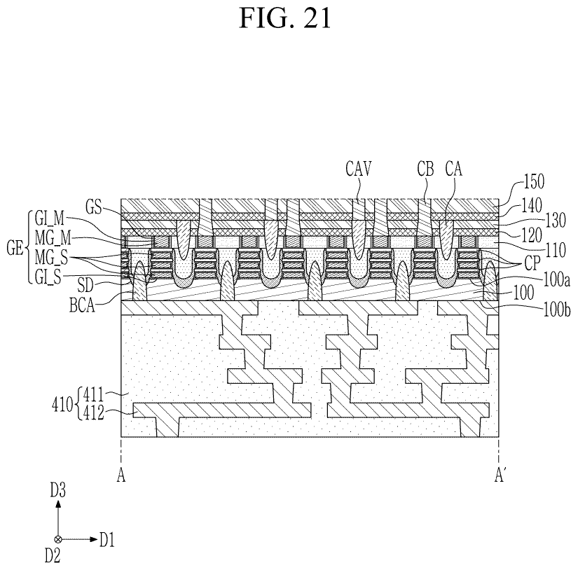

FIG. 21 to FIG. 26 are intermediate drawings illustrating a manufacturing method of a semiconductor device according to some embodiments. For better understanding and ease of description, any content that overlaps with that described above in FIG. 11 will be briefly explained or omitted

FIG. 21 to FIG. 26 are drawings corresponding to the cross-sectional views taken along line A-A′ of FIG. 5.

Referring to FIG. 21, a lower wire structure 410 may be formed on a second surface 100b of the substrate 100 before an upper wire structure 210, which will be described later, is formed on a first surface 100a of the substrate 100. Accordingly, a lower wire structure 410 including lower wires 412 and a lower insulating layer 411 may be positioned on the second surface 100b of the substrate 100.

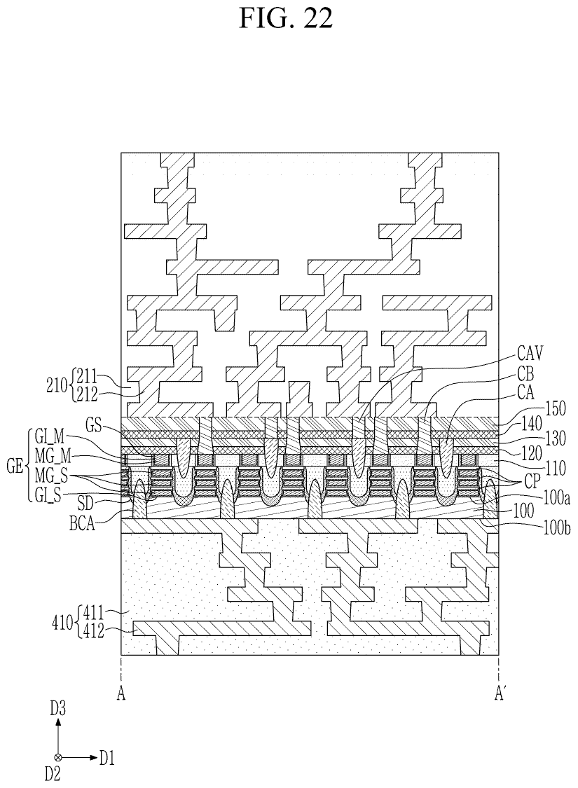

Referring to FIG. 22, in a state where a lower wire structure 410 is formed on a second surface 100b of a substrate 100, an upper wire structure 210 may be formed on a first surface 100a of a substrate 100.

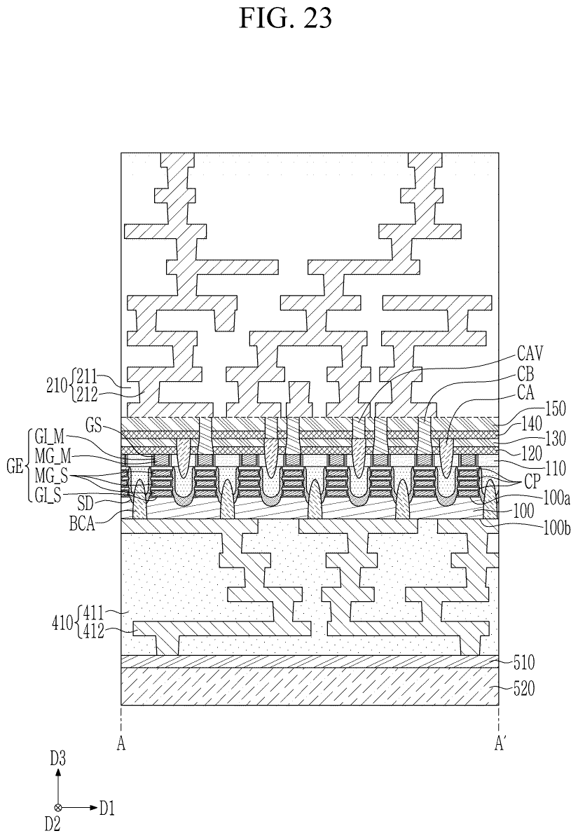

Referring to FIG. 23, a second support substrate 520 may be joined to the lower wire structure 410.

According to an embodiment, a second adhesive layer 510 may be formed on a second support substrate 520. Next, the second support substrate 520 and the lower wire structure 410 may be joined using the second adhesive layer 510. Accordingly, the second adhesive layer 510 may cover the lower wire structure 410. One surface of the second adhesive layer 510 may be in contact with the lower wire structure 410, and the other surface of the second adhesive layer 510 may be in contact with the second support substrate 520.

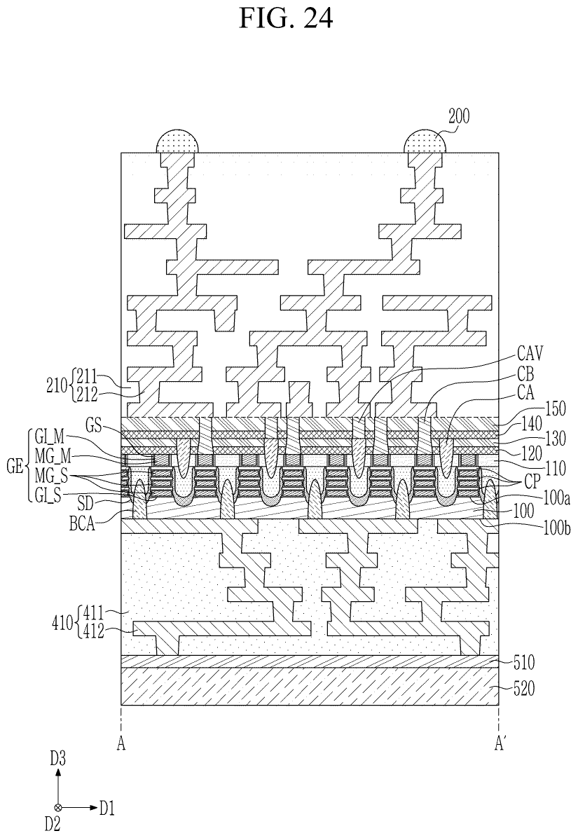

Referring to FIG. 24, a plurality of first bumps 200 may be formed that are connected to at least a portion of the upper wires 212 on the upper wire structure 210. Although not explicitly shown in FIG. 24, a plurality of first bumps 200 may be positioned along the edge of the device region where the device is positioned. A plurality of first bump 200 may not be positioned in the central region within the device region where the device is positioned.

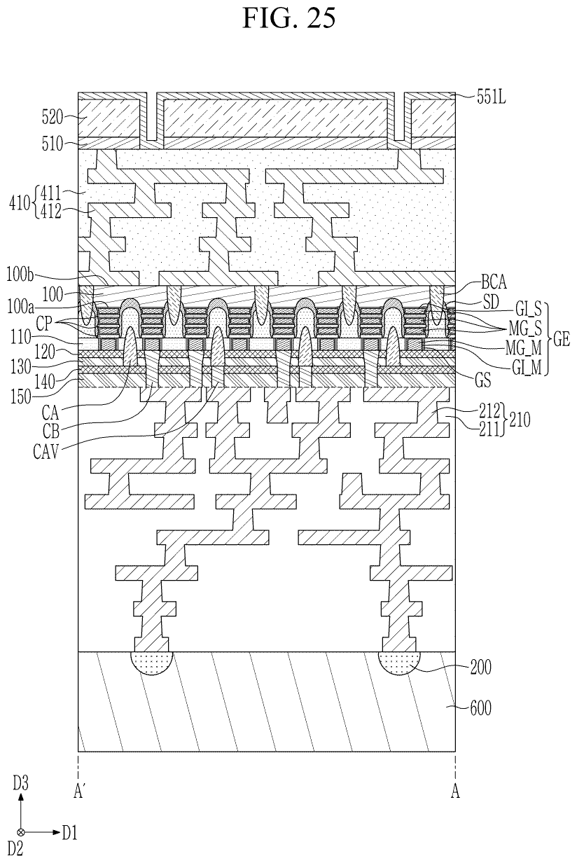

Referring to FIG. 25, a second passivation layer 600 covering a plurality of first bumps 200 may be formed. According to an embodiment, the second passivation layer 600 may cover each of the side and top surfaces of a plurality of first bumps 200. According to an embodiment, the second passivation layer 600 may include an organic material. For example, the second passivation layer 600 may include a photoresist.

According to an embodiment, the substrate 100 may be rotated so that the first surface 100a of the substrate 100 is facing downward. Accordingly, the second passivation layer 600 may be positioned below, and the second support substrate 520 may be positioned above.

According to an embodiment, through holes may be formed penetrating a second support substrate 520, and a second metal nitride material layer 551L may be conformally formed on an inner surface of the through holes. The second metal nitride material layer 551L may be in contact with the lower wires 412, which overlap the through holes and the third direction D3. Additionally, a second metal nitride material layer 551L may be formed on the surface of the second support substrate 520.

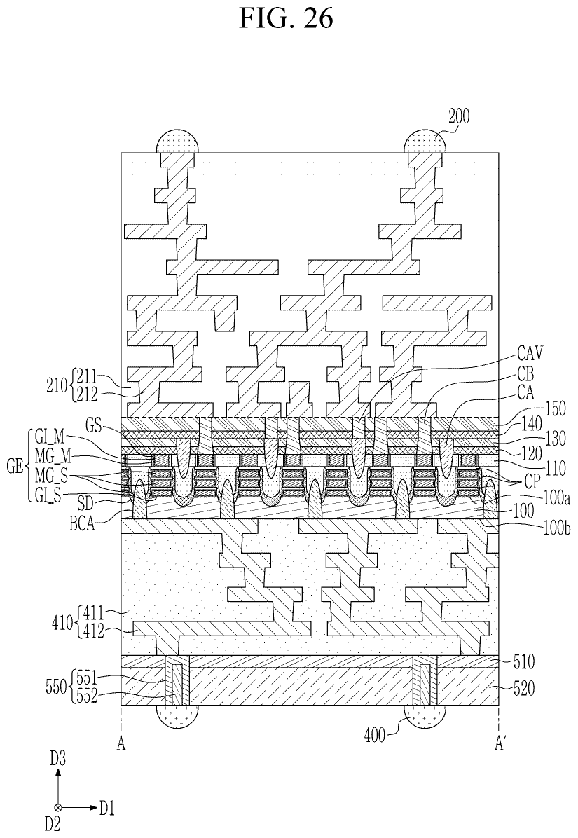

Referring to FIG. 26, a second metal pattern 552 may be formed on the second metal nitride material layer 551L illustrated in FIG. 25. According to an embodiment, the second metal pattern 552 may be formed through a chemical vapor deposition (CVD) process using the second metal nitride material layer 551L as a seed. Although not explicitly shown, the second metal pattern 552 may be formed to cover the second metal nitride material layer 551L.

Afterwards, at least a portion of the second metal nitride material layer 551L may be removed through a chemical mechanical polishing (CMP) process. Specifically, a portion of the second metal nitride material layer 551L covering the lower surface of the second support substrate 520 may be removed. At this time, among the second metal pattern 552, a portion covering the second metal nitride material layer 551L on the lower surface of the second support substrate 520 may be removed together.

Through the etching process of this step, the second metal nitride material layer 551L may have a shape that covers the side and upper surfaces of the second metal pattern 552. In other words, the second metal nitride layer 551 may be formed through the etching process.

Accordingly, a second through-via 550 penetrating the second support substrate 520 may be formed.

According to an embodiment, a plurality of second bumps 400 connected to a second through-via 550 may be formed on a second support substrate 520. Although not explicitly shown in FIG. 26, a plurality of second bumps 400 may be positioned along the edge of the device region where the device is positioned. A plurality of second bump 400 may not be positioned in the central region within the device region where the device is positioned.

According to an embodiment, the second passivation layer 600 illustrated in FIG. 25 may be removed. Accordingly, as shown in FIG. 7, a structure may be formed in which a second adhesive layer 510 and a second support substrate 520 are positioned on a lower wire structure 410, a plurality of second bumps 400 are positioned on the second support substrate 520, and a plurality of first bumps 200 are positioned on an upper wire structure 210.

A method of manufacturing a semiconductor device according to an embodiment may include the steps of preparing a substrate including channel patterns and source/drain patterns alternately positioned in a first direction, and gate electrodes surrounding the channel patterns and extending in a second direction intersecting the first direction, forming an upper wire structure on a first surface of the substrate and connected to at least one of the source/drain patterns and the gate electrodes, forming a plurality of first bumps on the upper wire structure and connected to the upper wire structure, forming a lower wire structure on a second surface of the substrate facing the first surface and connected to at least one of the source/drain patterns and the gate electrodes, and forming a plurality of second bumps on the lower wire structure and connected to the lower wire structure.

A method of manufacturing a semiconductor device according to an embodiment may further include a step of forming a support substrate between the upper wire structure and the plurality of first bumps.

A method of manufacturing a semiconductor device according to an embodiment may further include a step of bonding the support substrate to the upper wire structure using an adhesive layer.

In a method of manufacturing a semiconductor device according to an embodiment, the adhesive layer may include SiCN, AlN, TEOS (tetraethylorthosilicate), or a combination thereof.

A method of manufacturing a semiconductor device according to an embodiment may further include a step of forming through-vias penetrating the support substrate and connecting between the plurality of first bumps and the upper wire structure.

In a method of manufacturing a semiconductor device according to an embodiment, one of the through-vias may include a metal pattern penetrating the support substrate, and a metal nitride layer surrounding a sidewall and a bottom surface of the metal pattern.

In a method of manufacturing a semiconductor device according to an embodiment, one of the plurality of first bumps may be configured to apply a signal to at least one of the source/drain patterns or the gate electrodes, and one of the plurality of second bumps may be configured to apply power to at least another of the source/drain patterns or the gate electrodes.

According to an embodiment, a method of manufacturing a semiconductor device includes the steps of preparing a substrate including channel patterns and source/drain patterns alternately positioned in a first direction, and gate electrodes surrounding the channel patterns and extending in a second direction intersecting the first direction, forming an upper wire structure connected to at least one of the source/drain patterns and the gate electrodes on a first surface of the substrate, forming a lower wire structure connected to at least one of the source/drain patterns and the gate electrodes on a second surface of the substrate opposing the first surface, and forming a plurality of bumps connected to at least one of the upper wire structure or the lower wire structure. The plurality of bumps may not be positioned in a first region of the substrate, but may be positioned in a second region surrounding the first region.

In a method of manufacturing a semiconductor device according to an embodiment, the substrate includes a semiconductor chip including a plurality of cell regions and a peripheral region positioned outside the plurality of cell regions, and the second region may correspond to an edge region of the semiconductor chip.

In a method of manufacturing a semiconductor device according to an embodiment, the substrate includes a plurality of cell regions, and the second region may correspond to an edge region of each of the plurality of cell regions.

Although an embodiment has been described in detail above, the scope of the present disclosure is not limited thereto, and various modifications and improvements made by a person of an ordinary skill in the art using the basic concept of the present disclosure defined in the following claims also fall within the scope of the present disclosure.

What is claimed is:

1. A semiconductor device comprising:
a substrate including a first surface and a second surface opposing each other;
active patterns spaced apart from each other along a first direction on the first surface of the substrate;
source/drain patterns respectively connected to both sides of the active patterns;
gate electrodes surrounding the active patterns and extending in a second direction intersecting the first direction;
an upper wire structure positioned on the first surface of the substrate and connected to a first one of the source/drain patterns or the gate electrodes;
a lower wire structure positioned on the second surface of the substrate and connected to a second one of the source/drain patterns or the gate electrodes;
a support substrate positioned on one of the upper wire structure or the lower wire structure;
first through-vias penetrating the support substrate and connected to the one of the upper wire structure or the lower wire structure;
a plurality of first bumps positioned on the support substrate and respectively connected to the first through-vias; and
a plurality of second bumps positioned on the other one of the upper wire structure or the lower wire structure and connected to the other one of the upper wire structure or the lower wire structure.

2. The semiconductor device of claim 1, wherein:
the support substrate is positioned on the upper wire structure, and
the plurality of second bumps are positioned on the lower wire structure and connected to the lower wire structure.

3. The semiconductor device of claim 2, wherein:
one of the plurality of first bumps is configured to apply a signal to the first one of the source/drain patterns or the gate electrodes, and
one of the plurality of second bumps is configured to apply power to the second one of the source/drain patterns or the gate electrodes.

4. The semiconductor device of claim 1, wherein:
the support substrate is positioned on the lower wire structure, and
the plurality of second bumps are positioned on the upper wire structure and connected to the upper wire structure.

5. The semiconductor device of claim 4, wherein:
one of the plurality of first bumps is configured to apply power to at least the second one of the source/drain patterns or the gate electrodes, and
one of the plurality of second bumps is configured to apply a signal to the first one of the source/drain patterns or the gate electrodes.

6. The semiconductor device of claim 1, further comprising:
an adhesive layer positioned between the support substrate and at least the one of the upper wire structure or the lower wire structure, wherein the first through-vias penetrate the adhesive layer and are connected to the one of the upper wire structure or the lower wire structure.

7. The semiconductor device of claim 6, wherein the adhesive layer includes SiCN, AlN, TEOS (tetraethyl orthosilicate), or a combination thereof.

8. The semiconductor device of claim 1, wherein one of the first through-vias includes:
a metal pattern penetrating the support substrate, and
a metal nitride layer surrounding at least a portion of the metal pattern.

9. A semiconductor device comprising:
a substrate including a first region and a second region surrounding the first region, the substrate having a first surface and a second surface opposing each other;
active patterns spaced apart from each other along a first direction on the first surface of the substrate;
source/drain patterns respectively connected to both sides of the active patterns;
gate electrodes surrounding the active patterns and extending in a second direction intersecting the first direction;
an upper wire structure positioned on the first surface of the substrate and connected to a first one of the source/drain patterns or the gate electrodes;
a lower wire structure positioned on the second surface of the substrate and connected to a second one of the source/drain patterns or the gate electrodes; and
a plurality of bumps connected to at least one of the upper wire structure or the lower wire structure, wherein the plurality of bumps are positioned in the second region, not in the first region.

10. The semiconductor device of claim 9, wherein:
the substrate includes a semiconductor chip comprising a plurality of cell regions and a peripheral region positioned outside the plurality of cell regions, and
the second region corresponds to an edge region of the semiconductor chip.

11. The semiconductor device of claim 9, wherein:
the substrate includes a plurality of cell regions, and
the second region corresponds to an edge region of each of the plurality of cell regions.

12. The semiconductor device of claim 9, wherein the plurality of bumps include:
a plurality of first bumps positioned on the upper wire structure and connected to the upper wire structure, and
a plurality of second bumps positioned below the lower wire structure and connected to the lower wire structure.

13. The semiconductor device of claim 12, wherein:
one of the plurality of first bumps is configured to apply a signal to the first one of the source/drain patterns or the gate electrodes through the upper wire structure, and
one of the plurality of second bumps is configured to apply power to at least the second one of the source/drain patterns or the gate electrodes through the lower wire structure.

14. The semiconductor device of claim 12, wherein:
one of the plurality of first bumps is configured to apply a signal to the first one of the source/drain patterns or the gate electrodes, and another of the plurality of first bumps is configured to apply power to a third one of the source/drain patterns or the gate electrodes,
one of the plurality of second bumps is configured to apply power to the second one of the source/drain patterns or the gate electrodes through the lower wire structure.

15. The semiconductor device of claim 14, further comprising a through electrode connecting the upper wire structure and the lower wire structure,
wherein a third one of the plurality of first bumps is configured to apply power to a fourth one of the source/drain patterns or the gate electrodes through the through electrode.

16. The semiconductor device of claim 12, wherein:
one of the plurality of first bumps is configured to apply a signal to the first one of the source/drain patterns or the gate electrodes through the upper wire structure, and
one of the plurality of second bumps is configured to apply power to the second one of the source/drain patterns or the gate electrodes, and another of the plurality of second bumps is configured to apply a signal to a third one of the source/drain patterns or the gate electrodes.

17. A semiconductor device comprising:
a plurality of first upper bumps and a first upper wire structure connected to signal lines;
a plurality of first lower bumps and a first lower wire structure positioned below the first upper wire structure and connected to power lines;
a first device positioned between the first upper wire structure and the first lower wire structure,
wherein the first device includes a plurality of first gate structures and first source/drain patterns positioned between the plurality of first gate structures; and
the plurality of first upper bumps and the plurality of first lower bumps are positioned along an edge of a device region where the first device is positioned.

18. The semiconductor device of claim 17, wherein:
one of the plurality of first upper bumps is configured to apply a signal to at least one of the first gate structures or at least one of the first source/drain patterns, and
one of the plurality of first lower bumps is configured to apply power to at least another of the first gate structures or at least another of the first source/drain patterns.

19. The semiconductor device of claim 17, further comprising:
a plurality of second lower bumps and a second lower wire structure positioned on the plurality of first upper bumps and connected to the power lines,
a plurality of second upper bumps and a second upper wire structure positioned on the second lower wire structure and connected to the signal lines,
a second device positioned between the second upper wire structure and the second lower wire structure,
wherein the second device including a plurality of second gate structures and second source/drain patterns positioned between the plurality of second gate structures, and
the plurality of second upper bumps and the plurality of second lower bumps are positioned along an edge of a device region where the second device is positioned.

20. The semiconductor device of claim 19, wherein:
one of the plurality of second upper bumps is configured to apply a signal to at least one of the second gate structures or at least one of the second source/drain patterns, and
one of the plurality of second lower bumps is configured to apply power to at least another of the second gate structures or at least another of the second source/drain patterns.
